(19) United States
(12) Patent Application Publication
(10) Pub. No.: US 2025/0274096 A1
(43) Pub. Date: Aug. 28, 2025

(54) ACOUSTIC WAVE DEVICE AND FILTER DEVICE

(71) Applicant: Murata Manufacturing Co., Ltd., Nagaokakyo-shi (JP)

(72) Inventors: Kentaro NAKAMURA, Nagaokakyo-shi (JP); Takuya YABU, Nagaokakyo-shi (JP)

(21) Appl. No.: 19/208,908

(22) Filed: May 15, 2025

Related U.S. Application Data
(63) Continuation of application No. PCT/JP2023/042232, filed on Nov. 24, 2023.

(30) Foreign Application Priority Data
Nov. 28, 2022 (JP) 2022-189464

(51) Int. Cl. H03H 9/02; H03H 9/56

(52) U.S. Cl. CPC H03H 9/02086; H03H 9/02228; H03H 9/568

(57) ABSTRACT

An acoustic wave device includes a piezoelectric layer, an IDT electrode on the piezoelectric layer and including first and second busbars and first and second electrode fingers, and reflectors on the piezoelectric layer and including reflector fingers. The first and second electrode fingers are each respectively connected at one end to the first and second busbars. Imaginary lines respectively connecting distal end portions of the second and first electrode fingers are defined as first and second envelopes. The IDT electrode includes an intersecting region. The piezoelectric layer includes a propagation axis. The first and second electrode fingers include a curved portion in the intersecting region. The reflector electrode fingers include a curved portion. At least one of the first and second envelopes includes a portion extending at an inclination relative to the propagation axis, and includes a bend at which a direction in which the portion extends changes.

### CROSS REFERENCE TO RELATED APPLICATIONS

This application claims the benefit of priority to Japanese Patent Application No. 2022-189464 filed on Nov. 28, 2022 and is a Continuation Application of PCT Application No. PCT/JP2023/042232 filed on Nov. 24, 2023. The entire contents of each application are hereby incorporated herein by reference.

### BACKGROUND OF THE INVENTION

### 1. Field of the Invention

The present invention relates to acoustic wave devices and filter devices.

### 2. Description of the Related Art

In the related art, acoustic wave devices are widely used for applications such as filters of mobile phones. International Publication No. 2011/108229 discloses an exemplary acoustic wave device. The acoustic wave device includes interdigital transducer (IDT) electrodes on a piezoelectric substrate. The electrode fingers of the IDT electrode include a curved shape. More specifically, each electrode finger extends in a curve from a center of a region where the IDT electrodes intersect to a common electrode.

In the IDT electrodes of the acoustic wave device in International Publication No. 2011/108229, the electrode finger pitch is narrower in a central portion than in an end portion in a direction in which the electrode fingers extend. This configuration effectively reduces spurious responses. This configuration, however, fails to sufficiently reduce leakage of acoustic wave energy, and thus fails to achieve a sufficiently high Q factor.

### SUMMARY OF THE INVENTION

Example embodiments of the present invention provide acoustic wave devices and filter devices that each reduce spurious waves and also improve the Q factor.

An acoustic wave device according to an example embodiment of the present invention includes a piezoelectric substrate, an IDT electrode, and a pair of reflectors. The piezoelectric substrate includes a piezoelectric layer. The IDT electrode is on the piezoelectric layer, and includes a pair of busbars and a plurality of electrode fingers. The pair of reflectors are provided on the piezoelectric layer. The pair of reflectors are opposed to each other across the IDT electrode, and each includes a plurality of reflector electrode fingers. The pair of busbars include a first busbar and a second busbar opposed to each other. The plurality of electrode fingers include a plurality of first electrode fingers and a plurality of second electrode fingers. The plurality of first electrode fingers are each connected at one end to the first busbar. The plurality second electrode fingers are each connected at one end to the second busbar. The plurality of first electrode fingers are interdigitate with the plurality of second electrode fingers. An imaginary line connecting distal end portions of the second electrode fingers is defined as a first envelope. An imaginary line connecting distal end portions of the first electrode fingers is defined as a second envelope. The IDT electrode includes an intersecting region between the first envelope and the second envelope. The piezoelectric layer includes a propagation axis. The first electrode fingers and the second electrode fingers each have a shape in plan view that includes a curved portion in the intersecting region. The plurality of reflector electrode fingers each have a shape in plan view that includes a curved portion. At least one of the first envelope or the second envelope includes a portion extending at an inclination relative to the propagation axis, and includes at least one bend at which a direction in which the portion extends changes.

A filter device according to an example embodiment of the present invention includes a plurality of acoustic wave resonators, and at least one of the acoustic wave resonators is an acoustic wave device according to an example embodiment of the present invention.

A filter device according to another example embodiment of the present invention includes a plurality of acoustic wave resonators. At least two of the plurality of acoustic wave resonators are each an acoustic wave device according to an example embodiment of the present invention. The acoustic wave device includes two acoustic wave devices, and the first busbars of the two acoustic wave devices are connected with each other.

A filter device according to another example embodiment of the present invention includes a plurality of acoustic wave resonators. At least two of the plurality of acoustic wave resonators are each an acoustic wave device according to an example embodiment of the present invention. The acoustic wave device includes two acoustic wave devices, and the second busbars of the two acoustic wave devices are connected with each other.

The acoustic wave device and the filter device according to example embodiments of the present invention make it possible to reduce spurious waves, and also improve the Q factor.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along a reference line represented by a two-dot chain line in FIG. 1.

FIG. 3 is a schematic plan view, for explaining the configuration of an IDT electrode according to the first example embodiment of the present invention, of a segment of the IDT electrode.

FIG. 4 is a schematic plan view of an acoustic wave device according to the related art.

FIG. 5 is a schematic plan view of an acoustic wave device according to a first reference example.

FIG. 6 is a schematic plan view of an acoustic wave device according to a comparative example.

FIG. 7 illustrates impedance-frequency characteristics according to the first example embodiment of the present invention, the first reference example, and the comparative example.

FIG. 8 illustrates the relationship between frequency and Q factor according to the first example embodiment of the present invention, the first reference example, and the comparative example.

FIG. 9 illustrates phrase characteristics according to the first example embodiment of the present invention, the first reference example, and the comparative example.

FIG. 10 is a schematic plan view of an acoustic wave device according to a second reference example.

FIG. 11 illustrates, for a case where the number of electrode finger pairs between bends is 10 or 20, the relationship between the envelope inclination angle and the peak value of the integrated waveform of a 2 MHz transverse mode.

FIG. 12 illustrates, for a case where the envelope inclination angle is about 5°, about 10°, or about 15°, the relationship between the number of electrode finger pairs between bends, and the peak value of the integrated waveform of a 2 MHZ transverse mode.

FIG. 13 is a schematic plan view of the vicinity of first offset electrodes according to a first modification of the first example embodiment of the present invention.

FIG. 14 illustrates reverse-velocity surfaces for acoustic waves propagating through a first piezoelectric substrate and a second piezoelectric substrate.

FIG. 15 illustrates the reverse-velocity surfaces for a longitudinal wave, a fast transversal wave, and a slow transversal wave in the first piezoelectric substrate.

FIG. 16 illustrates, for the IDT electrode according to the first example embodiment of the present invention and an IDT electrode according to a second modification thereof, the relationship between the absolute value |θ_{C_prop}| of the excitation angle, and the duty ratio.

FIG. 17 is a schematic plan view, for explaining the configuration of an IDT electrode according to a third modification of the first example embodiment of the present invention, of a segment of the IDT electrode.

FIG. 18 is a schematic plan view of an acoustic wave device according to a fourth modification of the first example embodiment of the present invention.

FIG. 19 is a schematic plan view of an acoustic wave device according to a second example embodiment of the present invention.

FIG. 20 is a schematic plan view of an acoustic wave device according to a third example embodiment of the present invention.

FIG. 21 illustrates, for an IDT electrode according to a fourth example embodiment of the present invention, the relationship between the absolute value |θ_{C_prop}| of the excitation angle, and the rate of change Δpitch in electrode finger pitch.

FIG. 22 is a schematic plan view of an acoustic wave device according to a fifth example embodiment of the present invention.

FIG. 23 illustrates, for an IDT electrode according to a sixth example embodiment of the present invention, the relationship between the absolute value |θ_{C_prop}| of the excitation angle, and the electrode finger thickness.

FIG. 24 is a schematic elevational cross-sectional view of an acoustic wave device according to a seventh example embodiment of the present invention.

FIG. 25 illustrates, in accordance with the seventh example embodiment of the present invention, the relationship between the absolute value |θ_{C_prop}| of the excitation angle in an excitation portion of the IDT electrode that is covered by a dielectric film, and the thickness of the dielectric film in the excitation portion.

FIG. 26 illustrates, in accordance with a modification of the seventh example embodiment of the present invention, the relationship between the absolute value |θ_{C_prop}| of the excitation angle in an excitation portion of the IDT electrode that is covered by a dielectric film, and the thickness of the dielectric film in the excitation portion.

FIG. 27 is a schematic elevational cross-sectional view of an acoustic wave device according to an eighth example embodiment of the present invention.

FIG. 28 is a schematic elevational cross-sectional view of an acoustic wave device according to a first modification of the eighth example embodiment of the present invention.

FIG. 29 is a schematic elevational cross-sectional view of an acoustic wave device according to a second modification of the eighth example embodiment of the present invention.

FIG. 30 is a schematic elevational cross-sectional view of an acoustic wave device according to a ninth example embodiment of the present invention.

FIG. 31 is a schematic elevational cross-sectional view of an acoustic wave device according to a tenth example embodiment of the present invention.

FIG. 32 is a schematic elevational cross-sectional view of an acoustic wave device according to a first modification of the tenth example embodiment of the present invention.

FIG. 33 is a schematic elevational cross-sectional view of an acoustic wave device according to a second modification of the tenth example embodiment of the present invention.

FIG. 34 is a schematic elevational cross-sectional view of an acoustic wave device according to a third modification of the tenth example embodiment of the present invention.

FIG. 35 is a circuit diagram of a filter device according to an eleventh example embodiment of the present invention.

FIG. 36 is a schematic plan view, according to the eleventh example embodiment of the present invention, of an area where series resonators are connected with each other.

FIG. 37 is a schematic plan view, according to a first modification of the eleventh example embodiment of the present invention, of an area where series resonators are connected with each other.

FIG. 38 is a schematic plan view, according to a second modification of the eleventh example embodiment of the present invention, of an area where series resonators are connected with each other.

FIG. 39 is a schematic plan view, according to a third modification of the eleventh example embodiment of the present invention, of an area where series resonators are connected with each other.

FIG. 40 is an enlarged schematic plan view of a portion of an IDT electrode according to a fifth modification of the first example embodiment of the present invention.

FIG. 41 is a schematic plan view of an acoustic wave device according to a sixth modification of the first example embodiment of the present invention.

FIG. 42 is a schematic plan view of an acoustic wave device according to a twelfth example embodiment of the present invention.

FIGS. 43A to 43D schematically illustrate angles defined for first and second line segments of a first envelope.

FIG. 44 is a schematic plan view of an acoustic wave device according to a first modification of the twelfth example embodiment of the present invention.

FIG. 45 is a schematic plan view of an IDT electrode according to a second modification of the twelfth example embodiment of the present invention, illustrating the vicinity of a first edge region and the vicinity of a second edge region.

FIG. 46 is a schematic plan view of an acoustic wave device according to a thirteenth example embodiment of the present invention.

FIG. 47 is a schematic plan view of an acoustic wave device according to a first modification of the thirteenth example embodiment of the present invention.

FIG. 48 is a schematic plan view of an acoustic wave device according to a second modification of the thirteenth example embodiment of the present invention.

FIG. 49 is a schematic plan view of an acoustic wave device according to a third modification of the thirteenth example embodiment of the present invention.

### DETAILED DESCRIPTION OF THE EXAMPLE EMBODIMENTS

Example embodiments of the present invention will now be described with reference to the drawings to clearly explain the present invention.

Various example embodiments described herein are for illustrative purposes only, and components or features described with respect to different example embodiments may be partially substituted for or combined with each other.

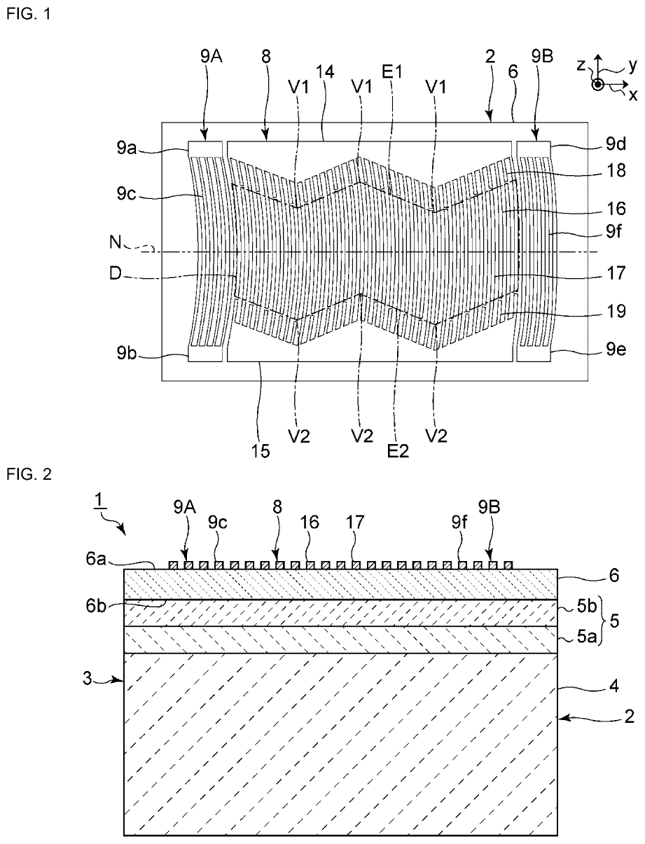

FIG. 1 is a schematic plan view of an acoustic wave device according to a first example embodiment of the present invention. FIG. 2 is a schematic cross-sectional view taken along a reference line represented by a two-dot chain line in FIG. 1.

As illustrated in FIGS. 1 and 2, an acoustic wave device 1 includes a piezoelectric substrate 2. The piezoelectric substrate 2 is a substrate having piezoelectricity. Specifically, as illustrated in FIG. 2, the piezoelectric substrate 2 includes a support 3, and a piezoelectric layer 6. More specifically, the support 3 includes a support substrate 4, and an intermediate layer 5. The intermediate layer 5 includes a first layer 5a, and a second layer 5b. The first layer 5a is disposed on the support substrate 4. The second layer 5b is disposed on the first layer 5a. The piezoelectric layer 6 is disposed on the second layer 5b. The layer composition of the piezoelectric substrate 2 is not limited to that described above. In another example, the intermediate layer 5 may be a single layer of a dielectric film. In another example, the piezoelectric substrate 2 may include only the piezoelectric layer 6.

The piezoelectric layer 6 of the acoustic wave device 1 is made of piezoelectric single crystal, for example. In the piezoelectric layer 6, the propagation axis is in the X-propagation direction. The propagation axis extends parallel or substantially parallel to a reference line N illustrated in FIG. 1. The reference line N will be described later.

The piezoelectric layer 6 includes a first major surface 6a, and a second major surface 6b. The first major surface 6a and the second major surface 6b are opposed to each other. Of the first major surface 6a and the second major surface 6b, the second major surface 6b is located near the support substrate 4. An IDT electrode 8 is disposed on the first major surface 6a of the piezoelectric layer 6.

As illustrated in FIG. 1, the IDT electrode 8 includes a pair of busbars, and a plurality of electrode fingers. The busbars specifically include a first busbar 14 and a second busbar 15. The first busbar 14 and the second busbar 15 are opposed to each other. The electrode fingers specifically include a plurality of first electrode fingers 16 and a plurality of second electrode fingers 17. The first electrode fingers 16 are each connected at one end to the first busbar 14. The second electrode fingers 17 are each connected at one end to the second busbar 15. The first electrode fingers 16 and the second electrode fingers 17 each include a proximal end portion and a distal end portion. The first electrode finger 16 is connected at the proximal end portion to the first busbar 14. The second electrode finger 17 is connected at the proximal end portion to the second busbar 15. The first electrode fingers 16 is interdigitate with the second electrode fingers 17.

The IDT electrode 8 further includes a plurality of offset electrodes. The offset electrodes specifically include a plurality of first offset electrodes 18 and a plurality of second offset electrodes 19. The first offset electrodes 18 are each connected at one end to the first busbar 14. The first electrode finger 16 and the first offset electrode 18 are arranged alternately. The second offset electrodes 19 are each connected at one end to the second busbar 15. The second electrode finger 17 and the second offset electrode 19 are arranged alternately.

As with the first electrode fingers 16 and the second electrode fingers 17, the first offset electrodes 18 and the second offset electrodes 19 each include a proximal end portion and a distal end portion. The first electrode finger 16 and the first offset electrode 18 are each connected at the proximal end portion to the first busbar 14. The second electrode finger 17 and the second offset electrode 19 are each connected at the proximal end portion to the second busbar 15. The distal end portion of the first electrode finger 16, and the distal end portion of the second offset electrode 19 face each other with a gap therebetween. The distal end portion of the second electrode finger 17, and the distal end portion of the first offset electrode 18 face each other with a gap therebetween. The first offset electrodes 18 and the second offset electrodes 19 need not necessarily be provided.

Hereinafter, the first electrode finger 16 and the second electrode finger 17 will sometimes be referred to simply as electrode finger or electrode fingers. The first offset electrodes 18 and the second offset electrodes 19 will sometimes be referred to simply as offset electrode or offset electrodes. The first busbar 14 and the second busbar 15 are sometimes referred to simply as busbar or busbars. The pitch or duty ratio of the offset electrode may differ from, for example, the electrode finger pitch or duty ratio of the IDT electrode 8 in an intersecting region, which will be described later.

The IDT electrode 8 of the acoustic wave device 1 has a constant electrode finger pitch. The electrode finger pitch is the center-to-center distance between the first electrode finger 16 and the second electrode finger 17 that are adjacent to each other. When the electrode finger pitch is p, the wavelength λ defined by the electrode finger pitch p is λ=2p.

As illustrated in FIG. 1, an imaginary line connecting the distal ends of the second electrode fingers 17 is defined as a first envelope E1, and an imaginary line connecting the distal ends of the first electrode fingers 16 is defined as a second envelope E2. The first envelope E1 includes a plurality of portions that are inclined relative to the propagation axis. The first envelope E1 includes a plurality of bends V1. More specifically, a bend refers to the location where the direction in which an envelope extends changes. According to the first example embodiment, the first envelope E1 has a wavy shape connecting mutually adjacent bends V1 by a straight line. Alternatively, the first envelope E1 may have a wavy shape connecting mutually adjacent bends V1 by a curve.

Similarly, the second envelope E2 includes a plurality of portions that are inclined relative to the propagation axis. The second envelope E2 includes a plurality of bends V2. The second envelope E2 has a wavy shape connecting mutually adjacent bends V2 by a straight line. Alternatively, the second envelope E2 may have a wavy shape connecting mutually adjacent bends V2 by a curve.

As described above, according to the first example embodiment, the first envelope E1 and the second envelope E2 both include the bends. It may suffice, however, that at least one of the first envelope E1 or the second envelope E2 includes at least one bend.

The region between the first envelope E1 and the second envelope E2 is the intersecting region D. More specifically, the intersecting region D refers to the region bounded by the following features: one of the electrode fingers that is located at one end in the direction of arrangement of the electrode fingers, one of the electrode fingers that is located at the other end in the direction of arrangement of the electrode fingers, the first envelope E1, and the second envelope E2. The first envelope E1 thus corresponds to an edge of the intersecting region D near the first busbar 14. The second envelope E2 corresponds to an edge of the intersecting region D near the second busbar 15. In the intersecting region D, mutually adjacent electrode fingers overlap each other when viewed in the direction in which the electrode fingers are arranged, that is, in the direction in which the first envelope E1 or the second envelope E2 extends.

A pair of reflectors 9A and 9B are disposed on the piezoelectric layer 6. The reflector 9A and the reflector 9B are opposed to each other across the IDT electrode 8 in the direction of arrangement of the electrode fingers of the IDT electrode 8. The reflector 9A includes a pair of reflector busbar 9a and 9b, and a plurality of reflector electrode fingers 9c. The reflector busbar 9a and the reflector busbar 9b are opposed to each other. The reflector electrode fingers 9c are connected at one end to the reflector busbar 9a. The reflector electrode fingers 9c are connected at the other end to the reflector busbar 9b. Similarly, the reflector 9B includes a pair of reflector busbars 9d and 9e, and a plurality of reflector electrode fingers 9f.

According to the first example embodiment, the first electrode fingers 16 and the second electrode fingers 17 each have a shape in plan view that includes a curved shape. Similarly, the reflector electrode fingers 9c of the reflector 9A, and the reflector electrode fingers 9f of the reflector 9B each have a shape in plan view that includes a curved shape. More specifically, for example, each electrode finger and each reflector electrode finger have the shape of a circular arc in plan view. As used herein, the expression “in plan view” refers to viewing from a position corresponding to the upper side in FIG. 2. In FIG. 2, for example, of the support substrate 4 and the piezoelectric layer 6, the piezoelectric layer 6 corresponds to the upper side. The respective shapes of the electrode fingers and the reflector electrode fingers, however, are not limited to those described above. It may suffice that the electrode fingers have a shape in plan view that includes a curved shape in the intersecting region D. It may suffice that the reflector electrode fingers may have a shape in plan view that includes a curved shape.

The configuration according to the first example embodiment has features (1) to (3) described below. (1) The first electrode fingers 16 and the second electrode fingers 17 each have a shape in plan view that includes a curved portion in the intersecting region D. (2) The reflector electrode fingers each have a shape in plan view that includes a curved portion. (3) The first envelope E1 and the second envelope E2 include a portion extending at an inclination relative to the propagation axis, and include at least one bend. It may suffice that at least one of the first envelope E1 or the second envelope E2 includes a portion extending at an inclination relative to the propagation axis, and includes at least one bend. The above-described configuration of the acoustic wave device 1 makes it possible to reduce spurious waves, and improve the Q factor. This will be explained below.

As described above, the first envelope E1 and the second envelope E2 each include a portion extending at an inclination relative to the propagation axis. The primary mode can thus be confined within the waveguide. Therefore, leakage of the primary mode can be reduced. This makes it possible to improve the Q factor. This further makes it possible to reduce transverse modes.

The electrode fingers of the IDT electrode 8 have a shape in plan view that includes a curved portion in the intersecting region D. This makes it possible to effectively reduce transverse modes and spurious waves outside the pass band. As used herein, expressions such as “outside the pass band of the acoustic wave device” mean frequencies lower than the resonant frequency, and frequencies higher than the anti-resonant frequency.

As with the electrode fingers of the IDT electrode 8, the reflector electrode fingers also have a shape in plan view that includes a curved portion. This makes it possible to effectively reduce leakage of the primary mode, and effectively improve the Q factor.

In addition, since the first envelope E1 or the second envelope E2 includes a portion extending at an inclination relative to the propagation axis, the gaps between the respective distal ends of the electrode fingers and the corresponding offset electrodes are arranged at an inclination relative to the propagation axis. This makes it possible to effectively reduce transverse modes. Further, the first envelope E1 and the second envelope E2 each include bends. This makes it possible to further improve the Q factor.

Hereinbelow, the first example embodiment will be described in further detail, and advantageous effects of the first example embodiment will be described in more detail.

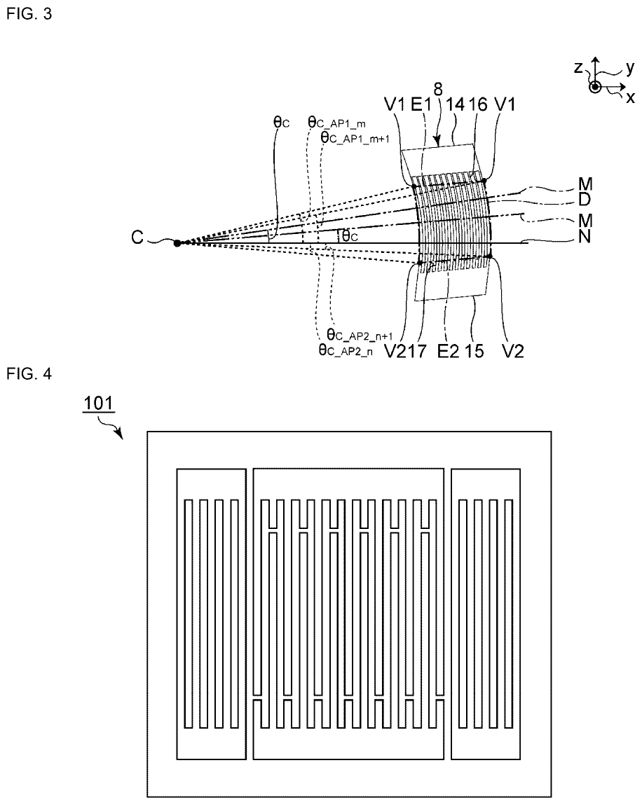

The IDT electrode 8 includes a plurality of segments each defined by the electrode finger passing through the bend V1 of the first envelope E1. The segments are arranged in the direction in which the propagation axis extends. FIG. 1 schematically shows four segments. With one of the segments as an example, the configuration of the IDT electrode 8 will now be described in detail with reference to FIG. 3.

FIG. 3 is a schematic plan view, for explaining the configuration of the IDT electrode according to the first example embodiment, of a segment of the IDT electrode.

The electrode fingers of the IDT electrode 8 each have a shape in plan view corresponding to a circular arc of a corresponding one of a plurality of concentric circles. Accordingly, the circles each including the circular arc defining the shape of each of the electrode fingers have the same or substantially the same center.

When the ellipticity of a circle or ellipse including an arc defining the shape of each of the electrode fingers is defined as α2/α1, the ellipticity α2/α1 according to the first example embodiment is about 1. If the arc defining the shape of each of the electrode fingers is a portion of an ellipse, then the ellipticity α2/α1 has a value other than about 1. The dimension α1 corresponds to a dimension along an axis that is one of the major and minor axes of the ellipse and that passes through the intersecting region D. The dimension α2 corresponds to a dimension along an axis that is one of the major and minor axes of the ellipse and that does not pass through the intersecting region D. The equation for the ellipticity in the XY-plane can be denoted as (x/α1)²+(y/α2)²=r², where r is an arbitrary constant.

When the center of a circle including an arc defining the shape of each of the electrode fingers is defined as a fixed point C, neither an extended line of the first envelope E1 nor an extended line of the second envelope E2 passes through the fixed point C. Consequently, a straight line passing through the fixed point C and through the first envelope E1 is not parallel or substantially parallel to the first envelope E1. Similarly, a straight line passing through the fixed point C and through the second envelope E2 is not parallel or substantially parallel to the second envelope E2.

As described above, the propagation axis extends parallel or substantially parallel to the reference line N. In this regard, the propagation axis is the axis of acoustic wave propagation. According to the first example embodiment, the reference line N is a straight line extending parallel or substantially parallel to the propagation axis, among straight lines passing through the intersecting region D and through the fixed point C. The angle between the reference line N and a straight line passing through the fixed point C is defined as θ_{C}. Among an infinite number of such straight lines passing through the fixed point C, the above-described straight line is shown as an example in FIG. 3. A positive direction of the angle θ_{C} is herein defined as the counterclockwise direction in plan view. More specifically, the direction pointing from the second busbar 15 toward the first busbar 14 is the positive direction.

Upon application of alternating-current voltage to the IDT electrode 8, an acoustic wave is excited in the intersecting region D. The intersecting region D includes a plurality of portions each located on the corresponding one of an infinite number of straight lines passing through the fixed point C. FIG. 3 shows a straight line M as an example of the infinite number of straight lines passing through the fixed point C and through the intersecting region D. For example, an acoustic wave is excited in a portion of the intersecting region D that is located on the straight line M. Similarly, an acoustic wave is excited in each of the other portions located on the infinite number of straight lines (not illustrated) passing through the fixed point C and through the intersecting region D. That is, the acoustic wave device 1 has an excitation portion located on the straight line M, and excitation portions each located on the corresponding one of the infinite number of straight lines (not illustrated).

The angle θ_{C} is the angle between the reference line N, and a straight line passing through the fixed point C and through an excitation portion. An excitation angle θ_{C_prop} is defined as the angle between the reference line N and a direction, the direction being the direction of acoustic wave excitation at the point of intersection between each electrode finger and a straight line passing through the fixed point C and through an excitation portion of the intersecting region D. In the excitation portion through which the reference line N passes, the angle θ_{C} and the excitation angle θ_{C_prop} are, for example, 0°. Different excitation portions have different excitation angles θ_{C_prop}, and consequently different acoustic wave propagation characteristics. In this regard, according to the first example embodiment, the duty ratio is varied among the excitation portions to make all of the excitation portions have the same or substantially the same resonant frequencies or anti-resonant frequencies. Excitation portions with the same or substantially the same absolute value |θ_{C_prop}| of the excitation angle have the same or substantially the same duty ratio. The above-described configuration of the IDT electrode 8 helps to reduce degradation of the resonance characteristics. Alternatively, however, the duty ratio may be constant.

In an excitation portion, the angle θ_{C} and the excitation angle θ_{C_prop} are the same or substantially the same. Hereinafter, for example, in describing the details of the configuration according to the present example embodiment, reference will be made sometimes to one of the angle θ_{C} and the excitation angle θ_{C_prop}. However, the difference between the angle θ_{C} and the excitation angle θ_{C_prop} is not significant enough to alter the intended operation and advantageous effects. When the ellipticity α2/α1 is about 1, that is, when the electrode fingers have the shape of a circular arc, the angle θ_{C} and the excitation angle θ_{C_prop} are equal or substantially equal.

When it is stated herein that one frequency and the other frequency are the same or substantially the same, this means that the absolute value of the difference between the two frequencies is, for example, less than or equal to about 10% of a reference frequency. A reference frequency refers to the frequency when the excitation angle θ_{C_prop} is about 0°. In the intersecting region D, the absolute value of the difference between the highest and lowest resonant frequencies of the primary mode is, for example, preferably less than or equal to about 2%, and more preferably less than or equal to about 18, of the reference frequency. Alternatively, in the intersecting region D, the absolute value of the difference between the highest and lowest anti-resonant frequencies of the primary mode is, for example, preferably less than or equal to about 2%, and more preferably less than or equal to about 1%, of the reference frequency. The configuration described above allows the resonance characteristics to be improved more reliably.

The IDT electrode 8 of the acoustic wave device 1 has a constant electrode finger pitch. Accordingly, when the wavelength defined by the electrode finger pitch is λ, in the IDT electrode 8, the wavelength λ is constant irrespective of the excitation angle θ_{C_prop}.

The angle θ_{C} between the reference line N, and a straight line passing through the fixed point C and through the bend V1 of the first envelope E1 is defined as a first intersecting angle θ_{C_AP1_k}. The index k is a natural number. The first intersecting angle θ_{C_AP1_k} can be defined for each individual bend V1. Specifically, the index k for the first intersecting angle θ_{C_AP1_k} is numbered as 1, 2, 3, . . . in order from the bend V1 closest to the fixed point C. Thus, the closer the bend V1 is to the fixed point C, the smaller the value of k for the corresponding first intersecting angle θ_{C_AP1_k}. For the segment of the IDT electrode 8 in FIG. 3, for example, such first intersecting angles are labeled as θ_{C_AP1_m} and θ_{C_AP1_m+1}. The index m is a natural number.

Similarly, the angle θ_{C} between the reference line N and a straight line passing through the fixed point C and through the bend V2 of the second envelope E2 is defined as a second intersecting angle θ_{C_AP2_k}. The closer the bend V2 is to the fixed point C, the smaller the value of k for the corresponding second intersecting angle θ_{C_AP2_k}. For the segment of the IDT electrode 8 in FIG. 3, for example, such second intersecting angles are labeled as θ_{C_AP2_n} and θ_{C_AP2_n+1}. The index n is a natural number.

As described above, according to the first example embodiment, the straight line connecting the fixed point C and the distal end of the second electrode finger 17 is not parallel or substantially parallel to the first envelope E1. Consequently, θ_{C_AP1_m}≠θ_{C_AP1_m+1}. Similarly, the straight line connecting the fixed point C and the distal end of the first electrode finger 16 is not parallel or substantially parallel to the second envelope E2. Consequently, θ_{C_AP2_n}≠θ_{C_AP2_n+1}.

Returning to FIG. 1, the reflector electrode fingers 9c of the reflector 9A, and the reflector electrode fingers 9f of the reflector 9B each have a shape in plan view corresponding to a circular arc defining the corresponding one of a plurality of concentric circles. The center of the circles each including the circular arc defining the shape of the corresponding one of the reflector electrode fingers 9c and the reflector electrode fingers 9f coincides with the fixed point C. Each reflector electrode finger may have a curved or straight shape different from the shape of the electrode fingers of the IDT electrode 8 in an excitation portion. Parameters such as the reflector electrode finger pitch or duty ratio for each reflector may differ from those for the electrode fingers of the IDT electrode 8 in an excitation portion. The reflector electrode finger pitch is the center-to-center distance between mutually adjacent reflector electrode fingers. The reflector electrode fingers of each reflector may be formed by a pattern different from the shape of the electrode fingers of the IDT electrode 8 in an excitation portion.

An acoustic wave is excited in one of the following three kinds of directions. A first kind of direction is a direction perpendicular or substantially perpendicular to the direction in which the electrode fingers extend. A second kind of direction is a direction connecting mutually adjacent electrode fingers at the shortest distance. A third kind of direction is a direction parallel or substantially parallel to the electric-field vector generated between the electrode fingers.

Each electrode finger includes, in plan view, a pair of edges connecting the proximal end portion and the distal end portion. The edges both have a curved shape. Unless specifically noted otherwise, the direction in which the electrode fingers extend is herein defined as follows. First, when, for a given portion of each electrode finger, an imaginary line parallel or substantially parallel to the reference line connects the two edges of the electrode finger, the centroid of the portion located on the imaginary line is defined as a representative point for the imaginary line. For each electrode finger, an infinite number of such imaginary lines can be drawn, and thus an infinite number of such representative points exist. The direction of the tangent to a curve defined by the connection of these representative points is defined as the direction in which the electrode fingers extend. For each individual position on each electrode finger, the electrode finger extends in a different direction. For example, if the intersecting region includes a plurality of curved regions, and a different reference line exists for each curved region, the direction in which the reference line extends in a curved region for which an imaginary line is drawn may be defined as the direction in which the imaginary line extends.

With an acoustic wave device 101 according to the related art in FIG. 4, the direction of acoustic wave excitation is the same or substantially the same for each of the three kinds of directions described above. In contrast, according to the first example embodiment in FIG. 3, in a curved region, the electrode fingers each have, in plan view, the shape of an arc of a circle centered at the fixed point C. In this case, the direction of acoustic wave excitation is the first kind of direction. That is, the direction of acoustic wave excitation is represented by the direction perpendicular or substantially perpendicular to the direction in which the electrode fingers extend.

As described above, in the piezoelectric layer 6, the propagation axis is in the X-propagation direction. The propagation axis may be not only in the X-propagation direction, but also in a direction perpendicular or substantially perpendicular to either the 90° X-propagation direction or the direction in which the electrode fingers of the IDT electrode 8 extend. The reference line N need not necessarily extend parallel or substantially parallel to the propagation axis.

Advantageous effects of the first example embodiment will now be described through comparison of the first example embodiment, a first reference example, and a comparative example.

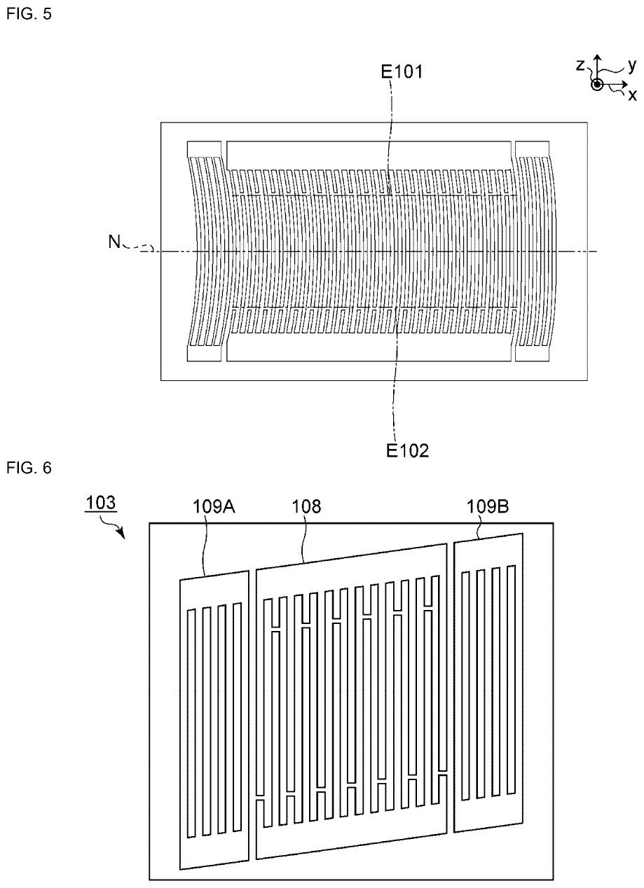

As illustrated in FIG. 5, the first reference example differs from the first example embodiment in that neither a first envelope E101 nor a second envelope E102 is inclined relative to the propagation axis. The first example embodiment, the first reference example, and the comparative example are compared in terms of the impedance-frequency characteristics, the relationship between frequency and Q factor, and the phase characteristics.

An acoustic wave device according to the comparative example is an inclined acoustic wave device according to the related art as illustrated in FIG. 6. In an acoustic wave device 103 according to the comparative example, an IDT electrode 108, a reflector 109A, and a reflector 109B each include straight electrode fingers. The first busbar and the second busbar each extend at an inclination relative to a direction orthogonal or substantially orthogonal to the direction in which the electrode fingers extend. The intersecting region of the IDT electrode 108 has the shape of a parallelogram.

The design parameters of the acoustic wave device 1 according to the first example embodiment are as follows. In this regard, the dimension of the offset electrode in the direction connecting its proximal and distal end portions is defined as the length of the offset electrode. The gap between the distal end portion of the electrode finger, and the distal end portion of the offset electrode has a dimension, defined as a gap length, in a direction in which the electrode finger and the offset electrode face each other. According to the first example embodiment, the gap between the distal end portion of the second electrode finger and the distal end portion of the first offset electrode has the same or substantially the same gap length as the gap between the distal end portion of the first electrode finger and the distal end portion of the second offset electrode.

Support substrate 4: material: Si; surface orientation: (100); ψ of the Euler angles (φ, θ, ψ): about 45°

First layer 5a: material: SiN; thickness: about 0.45λ

Second layer 5b: material: SiO₂; thickness: about 0.3365λ

Piezoelectric layer 6: material: rotated Y-cut 50° X-propagation LiTaO₃; thickness: about 0.3λ

IDT electrode 8: material: Al; thickness: about 0.07λ

Number of electrode finger pairs of the IDT electrode 8: 100 pairs

Ellipticity α2/α1 of the shape of the electrode finger: about 1

First intersecting angle θ_{C_AP1_1}: about 7.5°

First intersecting angle θ_{C_AP1_2}: about 3°

Second intersecting angle θ_{C_AP2_1}: about 3°

Second intersecting angle θ_{C_AP2_2}: about 4°

Absolute value of the inclination angle of each of the first and second envelopes E1 and E2 relative to the propagation axis: about 10°

Wavelength λ: about 2 μm

Duty ratio: about 0.5 in the excitation portion with the excitation angle θ_{C_prop} of about 0°

Length of the first offset electrode 18 and the second offset electrode 19: about 3.5λ

Gap length: about 0.135λ

Reflector 9A and reflector 9B: number of reflector electrode finger pairs: 20 pairs

Design parameters used for the first reference example are similar to those according to the first example embodiment, except that the absolute value of the inclination angle of each of the first and second envelopes E101 and E102 relative to the propagation axis is about 0°.

For the comparative example, the direction in which the electrode fingers extend is defined as an electrode-finger extending direction, and a dimension of the intersecting region in the electrode-finger extending direction is defined as an intersecting width. The IDT electrode 108 of the acoustic wave device according to the comparative example has an intersecting width of about 25λ. The IDT electrode 108 has 100 pairs of electrode fingers, and the reflector 109A and the reflector 109B each have 20 pairs of reflector electrode fingers. The IDT electrode 108 has a duty ratio of about 0.5. Each busbar is inclined at an angle of about 7.5° relative to a direction orthogonal or substantially orthogonal to the electrode-finger extending direction.

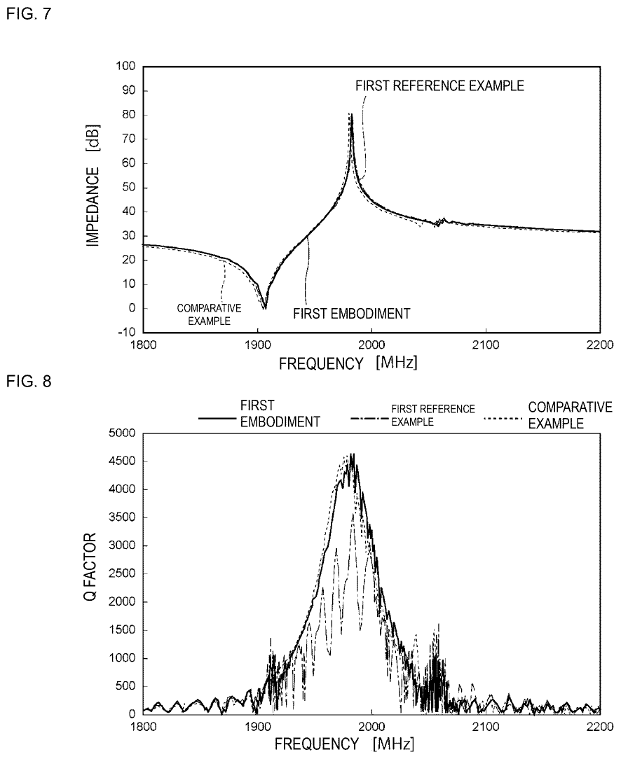

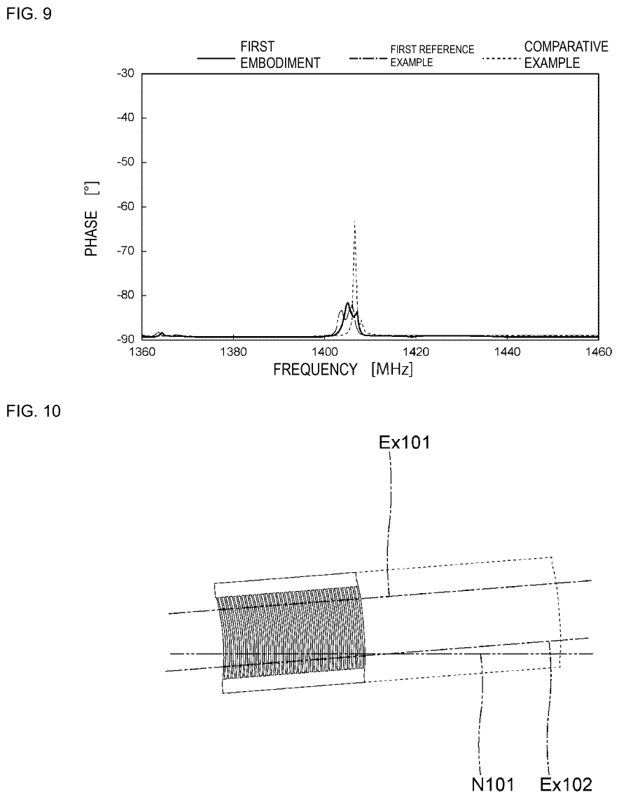

FIG. 7 illustrates impedance-frequency characteristics according to the first example embodiment, the first reference example, and the comparative example. FIG. 8 illustrates the relationship between frequency and Q factor according to the first example embodiment, the first reference example, and the comparative example. FIG. 9 illustrates phrase characteristics according to the first example embodiment, the first reference example, and the comparative example.

As illustrated in FIG. 7, the first example embodiment, the first reference example, and the comparative example do not have much of a difference in resonance characteristics. However, although not illustrated in FIG. 7, with the first reference example, transverse modes occur between the resonant frequency and the anti-resonant frequency. In contrast, with the first example embodiment, such transverse modes are reduced. This is due to the fact that according to the first example embodiment, the first envelope and the second envelope include a portion inclined relative to the propagation axis. Further, it can be observed from FIG. 8 that the first example embodiment has a higher Q factor than the first reference example.

As illustrated in FIG. 9, the comparative example include large spurious waves. The spurious waves in FIG. 9 are Rayleigh waves. The first example embodiment includes reduced spurious waves relative to the comparative example. The first reference example also includes reduced spurious waves relative to the comparative example. The reduced spurious waves according to the first example embodiment and the first reference example are due to the fact that in plan view, the electrode fingers have a curved shape in the intersecting region.

As described above, the first example embodiment makes it possible to achieve both reduced spurious waves and improved Q factor. This is because according to the first example embodiment, the first envelope E1 and the second envelope E2 include bends. This will now be explained in detail with reference to a second reference example.

FIG. 10 schematically illustrates an acoustic wave device according to the second reference example, which differs from the acoustic wave device according to the first example embodiment in that the first envelope and the second envelope include no bends. A one-dot chain line Ex101 in FIG. 10 is an imaginary line including the first envelope and an extended line of the first envelope. A one-dot chain line Ex102 is an imaginary line including the second envelope and an extended line of the second envelope. According to the second reference example, the first envelope and the second envelope are inclined relative to the propagation axis.

One general approach to improve the resonance characteristics of acoustic wave devices is to increase the number of pairs of electrode fingers of the IDT electrode. In acoustic wave devices, among various components of the primary mode, the components that propagate in the direction in which the propagation axis extends generally have the most favorable characteristics. A two-dot chain line N101 in FIG. 10 represents a portion where the primary mode propagates in the direction in which the propagation axis extends. Specifically, the two-dot chain line N101 is an imaginary line representing a portion where the direction normal to the direction in which the curved electrode fingers extend is parallel or substantially parallel to the direction in which the propagation axis extends.

For the second reference example, one exemplary way to improve the Q factor and thus the resonant characteristics would be to increase the number of electrode fingers as indicated by the dashed line in FIG. 10. This would, however, result in the IDT electrode including many electrode fingers that are not located on the two-dot chain line N101. In other words, this would result in a greater proportion of the IDT electrode being occupied by a portion where the primary mode does not propagate in the direction in which the propagation axis extends. This in turn makes it difficult to sufficiently improve the Q factor.

In contrast, according to the first example embodiment, the portion located on the reference line N in FIG. 1 is where the primary mode propagates in the direction in which the propagation axis extends. In the acoustic wave device 1, the first envelope E1 and the second envelope E2 include bends. As a result, in the direction in which the propagation axis extends, the proportion of the portion where the primary mode propagates can be increased. Therefore, the Q factor can be effectively increased.

Preferably, for example, at least about 50% of the electrode fingers include a portion where the direction normal to the direction in which these electrode fingers extend is aligned with the direction in which the propagation axis extends. More preferably, for example, at least about 80% of the electrode fingers include a portion where the direction normal to the direction in which these electrode fingers extend is aligned with the direction in which the propagation axis extends. The Q factor can be improved more reliably. According to the first example embodiment, all of the electrode fingers include a portion where the direction normal to the direction in which these electrode fingers extend is aligned with the direction in which the propagation axis extends. The Q factor can be effectively increased even more reliably.

As described above with reference to the first example embodiment, the first envelope E1 preferably includes the bends V1. This allows a further increased number of electrode fingers to include a portion where the direction normal to the direction in which these electrode fingers extend is aligned with the direction in which the propagation axis extends. Therefore, the Q factor can be improved more reliably.

As illustrated in FIG. 1, preferably, the second envelope E2 has a wavy shape including the bends V2, and is bent in the same direction as the first envelope E1. Specifically, the first envelope E1 includes a bend V1 where the first envelope E1 is bent to protrude toward the first busbar 14. Similarly, the second envelope E2 includes a bend V2 where the second envelope E2 is bent to protrude toward the first busbar 14. The bends V1 and V2 where the corresponding envelopes are bent to protrude toward the first busbar 14 are preferably arranged in the direction orthogonal or substantially orthogonal to the propagation axis.

Further, the first envelope E1 includes a bend V1 where the first envelope E1 is bent to protrude toward the second busbar 15. Similarly, the second envelope E2 includes a bend V2 where the second envelope E2 is bent to protrude toward the second busbar 15. The bends V1 and V2 where the corresponding envelopes are bent to protrude toward the second busbar 15 are preferably arranged in the direction orthogonal or substantially orthogonal to the propagation axis.

If the first envelope E1 and the second envelope E2 are bent in the same direction as described above, the change in the dimension of the intersecting region D in the direction orthogonal or substantially orthogonal to the propagation axis is relatively small. This enables stable acoustic wave propagation. Therefore, the characteristics of the primary mode can be improved.

Now, for the first example embodiment illustrated in FIG. 1, the conditions associated with the first envelope E1 and the second envelope E2 are varied for comparison of the influence of transverse modes on frequency characteristics under such varying conditions. Specifically, the influence of transverse modes is evaluated each time the number of electrode finger pairs between the bends V1 of the first envelope E1 and the inclination angle of the first envelope E1 relative to the propagation axis are changed. The first envelope E1 and the second envelope E2 have the same number of electrode finger pairs between the bends, and the same or substantially the same inclination angle relative to the propagation axis. Hereinafter, the inclination angle of each of the first and second envelopes E1 and E2 relative to the propagation axis will be sometimes referred to simply as envelope inclination angle.

Specifically, the influence of transverse modes is evaluated based on the peak value of the integrated waveform of the 2 MHz component (2 MHz AnyRipple), within the frequency band between the resonant frequency and the anti-resonant frequency. A smaller peak value indicates more effective reduction of transverse modes, and consequently a higher Q factor.

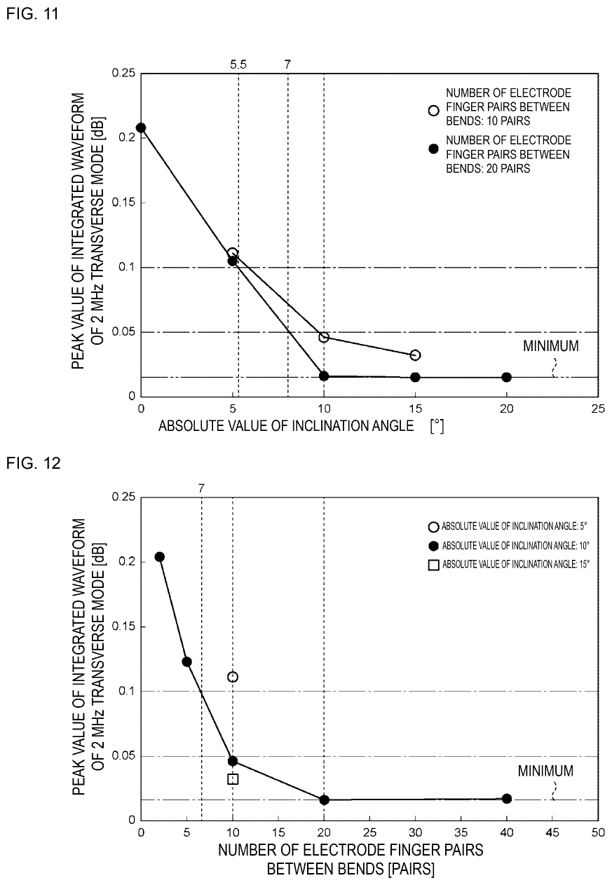

FIG. 11 illustrates, for a case where the number of electrode finger pairs between the bends is 10 or 20, the relationship between the envelope inclination angle and the peak value of the integrated waveform of the 2 MHz transverse mode. FIG. 12 illustrates, for a case where the envelope inclination angle is about 5°, about 10°, or about 15°, the relationship between the number of electrode finger pairs between the bends, and the peak value of the integrated waveform of the 2 MHZ transverse mode. The two-dot chain line in each of FIGS. 11 and 12 represents the peak value under the condition where the peak value becomes minimum.

As illustrated in FIG. 11, the influence of transverse modes is observed to decrease with increasing absolute value of the envelope inclination angle. As illustrated in FIG. 12, the influence of transverse modes is observed to decrease with increasing number of electrode finger pairs between the bends.

Preferably, for example, in the first envelope E1 in FIG. 1, twenty or more pairs of electrode fingers are provided between mutually adjacent bends V1 of the first envelope E1, and each portion of the first envelope E1 where the first envelope E1 is inclined relative to the propagation axis has an inclination angle with an absolute value greater than or equal to about 5.5°. In this case, as illustrated in FIG. 11, the peak value of the integrated waveform of the 2 MHz transverse mode can be made less than or equal to about 0.1 dB. More preferably, for example, the number of electrode finger pairs between the bends V1 is greater than or equal to 20, and each portion of the first envelope E1 where the first envelope E1 is inclined relative to the propagation axis has an inclination angle with an absolute value greater than or equal to about 7°. In this case, the above-described peak value can be made less than or equal to about 0.05 dB. Still more preferably, for example, the number of electrode finger pairs between the bends V1 is greater than or equal to 20, and each portion of the first envelope E1 where the first envelope E1 is inclined relative to the propagation axis has an inclination angle with an absolute value greater than or equal to about 10°. In this case, the peak value can be made minimum. In the above-described cases, transverse modes can be effectively reduced, and the Q factor can be effectively improved.

Preferably, for example, each portion of the first envelope E1 where the first envelope E1 is inclined relative to the propagation axis has an inclination angle with an absolute value greater than or equal to about 10°, and seven or more pairs of electrode fingers are provided between mutually adjacent bends V1 of the first envelope E1. In this case, as illustrated in FIG. 12, the peak value of the integrated waveform of the 2 MHZ transverse mode can be made less than or equal to about 0.1 dB. More preferably, for example, each portion of the first envelope E1 where the first envelope E1 is inclined relative to the propagation axis has an inclination angle with an absolute value greater than or equal to about 10°, and ten or more pairs of electrode fingers are provided between mutually adjacent bends V1 of the first envelope E1. In this case, the peak value can be made less than or equal to about 0.05 dB. Still more preferably, for example, each portion of the first envelope E1 where the first envelope E1 is inclined relative to the propagation axis has an inclination angle with an absolute value greater than or equal to about 10°, and twenty or more pairs of electrode fingers are provided between mutually adjacent bends V1 of the first envelope E1. In this case, the peak value can be made minimum. In the above-described cases, transverse modes can be effectively reduced, and the Q factor can be effectively improved.

Preferably, as illustrated in FIG. 1, the IDT electrode 8 includes the first offset electrodes 18 and the second offset electrodes 19. Consequently, the primary mode that has propagated from the intersecting region D toward each busbar can be reflected back toward the intersecting region D. This makes it possible to reduce loss of the primary mode, and improve the characteristics of the primary mode.

The first offset electrodes 18 preferably have a curved shape in plan view. The first offset electrodes 18 can thus be designed to match the frequency of the primary mode to be reflected by the first offset electrodes 18. This allows the main mode to be reflected with improved efficiency. Therefore, the characteristics of the primary mode can be effectively improved. Similarly, the second offset electrodes 19 preferably have a curved shape in plan view.

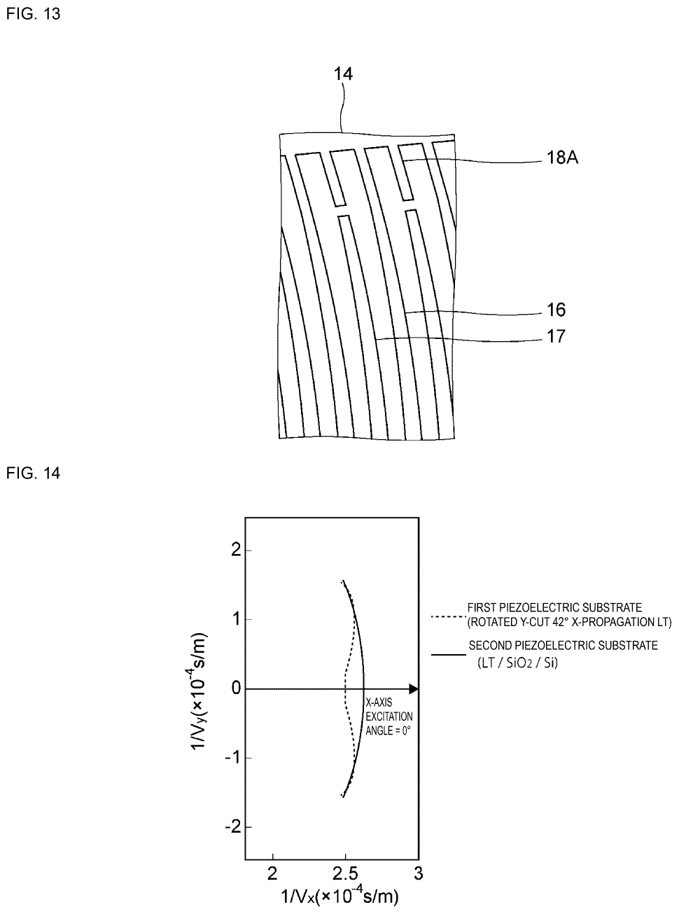

The offset electrodes need not necessarily have a curved shape in plan view. For example, according to a first modification of the first example embodiment in FIG. 13, a plurality of first offset electrodes 18A have a straight shape in plan view. Although not illustrated, the second offset electrodes also have a straight shape in plan view. In this case, the distance from the distal end portion of the first offset electrode 18A to the first busbar 14 can be reduced. Similarly, the distance from the distal end portion of the second offset electrode to the second busbar can be reduced. As a result, the electrical resistance of the IDT electrode can be reduced. Therefore, for a case where the acoustic wave device is used in a filter device, the above-described configuration makes it possible to limit an increase in insertion loss caused by the series resistance component. In addition, as with the first example embodiment, the above-described configuration makes it possible to reduce spurious waves, and improve the Q factor.

Returning now to FIG. 1, according to the first example embodiment, in plan view, the first busbar 14 has a wavy shape in a portion near the first envelope E1. The first busbar 14, and the first envelope E1 have a constant distance therebetween in the direction orthogonal or substantially orthogonal to the propagation axis. Further, the first offset electrodes 18 have a constant length. The gap between the distal end portion of the second electrode finger 17 and the distal end portion of the first offset electrode 18 similarly has a constant gap length. The above-described configuration allows the gap length to be made constant in conformity with the shape of the first envelope E1, without increasing the length of the first offset electrodes 18. This makes it possible to more reliably reduce leakage of the primary mode without increasing the electrical resistance of the IDT electrode 8.

Similarly, the second busbar 15 and the second envelope E2 have a constant distance therebetween in the direction orthogonal or substantially orthogonal to the propagation axis. The second offset electrodes 19 have a constant length. The gap between the distal end portion of the first electrode finger 16 and the distal end portion of the second offset electrode 19 similarly has a constant gap length. This makes it possible to more reliably reduce leakage of the primary mode without increasing the electrical resistance of the IDT electrode 8.

According to the first example embodiment, a reduction of spurious waves and other advantageous effects are obtained by different characteristics of acoustic wave propagation in each excitation portion. This will now be explained in detail. However, the configuration of the IDT electrode 8 according to the first example embodiment is illustrative, and not intended to limit the configuration of the IDT electrode according to the present invention to the particular configuration described below.

The phase velocity of acoustic waves has dependence on the excitation angle θ_{C_prop}, and has unique characteristics that vary with the composition of a substrate. The reciprocal of the phase velocity corresponds to the reverse-velocity surface. Therefore, the relationship between the excitation angle θ_{C_prop} and the phase velocity is generally consistent with the reverse-velocity surface of the piezoelectric substrate. In this regard, FIG. 14 illustrates an example of the reverse-velocity surfaces for piezoelectric substrates with different layer compositions. For example, one of the piezoelectric substrates is made solely of rotated Y-cut, 42° X-propagation LiTaO₃ (LT). This substrate is referred to as a first piezoelectric substrate. Another piezoelectric substrate is a bonded substrate including a piezoelectric layer and a support substrate. This substrate is referred to as a second piezoelectric substrate. More specifically, the second piezoelectric substrate includes, for example, a silicon substrate with a surface orientation of (100), a silicon oxide film, and a lithium tantalate layer that are stacked in this order. Even when the substrate has other surface orientations such as (110) or (111), this does not change the concave-convex profiles of the reverse-velocity surface.

FIG. 14 illustrates reverse-velocity surfaces for acoustic waves propagating through the first piezoelectric substrate and the second piezoelectric substrate.

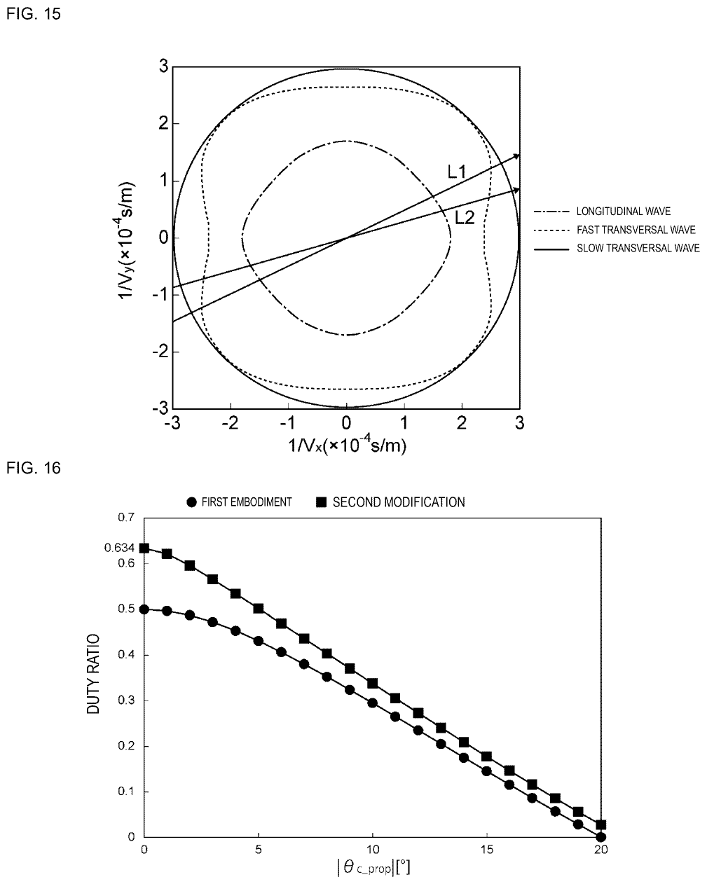

The x-axis in FIG. 14 corresponds to the case when the x-axis is parallel or substantially parallel to the propagation axis. That is, the x-axis corresponds to the case when the excitation angle θ_{C_prop} is about 0°. The respective reverse-velocity surfaces of the first and second piezoelectric substrates are both line-symmetric with respect to the x-axis. The reverse-velocity surface of the first piezoelectric substrate is concave. In contrast, the reverse-velocity surface of the second piezoelectric substrate is convex. It can be thus appreciated that the dependence that an acoustic wave propagating through a substrate has on the excitation angle θ_{C_prop} varies with the composition of the substrate. Further, for different acoustic wave modes, the dependence on the excitation angle θ_{C_prop} varies within the same substrate. This will now be described with reference to FIG. 15.

FIG. 15 illustrates the reverse-velocity surfaces for a longitudinal wave, a fast transversal wave, and a slow transversal wave in the first piezoelectric substrate.

As illustrated in FIG. 15, the reverse-velocity surfaces for the three different modes of acoustic waves, the longitudinal wave, the fast transversal wave, and the slow transversal wave, differ from each other. The regions along arrows L1 and L2 in FIG. 15 each correspond to an exemplary case where the excitation angle θ_{C_prop} is other than 0°. The separation between the respective reverse-velocity surfaces of the slow and fast transversal waves in the region along the arrow L1 differs from the separation between the respective reverse-velocity surfaces of the slow and fast transversal waves in the region along the arrow L2. Similarly, the separation between the respective reverse-velocity surfaces of the fast transversal wave and the longitudinal wave in the region along the arrow L1 differs from the separation between the respective reverse-velocity surfaces of the fast transversal wave and the longitudinal wave in the region along the arrow L2. That is, the separation between the reverse-velocity surfaces for different modes differs between excitation portions with different excitation angles θ_{C_prop}. This similarly applies to the relationship between the primary mode used in the acoustic wave device, and spurious waves.

In this case, in the acoustic wave device 1 according to the first example embodiment, the resonant frequency or anti-resonant frequency of the primary mode is made the same or substantially the same in all of the excitation portions. Consequently, the frequencies of spurious waves differ for different excitation portions. The spurious waves and transverse modes that are outside the pass band thus become dispersed. Therefore, spurious waves and transverse modes that are outside the pass band can be reduced.

According to the first example embodiment, the resonant frequency or anti-resonant frequency is made the same or substantially the same in each excitation portion. The primary mode can be thus excited in a suitable manner. Therefore, degradation of the resonance characteristics can be reduced more reliably.

In addition, according to the first example embodiment, the first intersecting angle θ_{C_AP1_k} differs between mutually adjacent bends V1 of the first envelope E1. Similarly, the second intersecting angle θ_{C_AP2_k} differs between mutually adjacent bends V2 of the second envelope E2. Consequently, each individual electrode finger differs in the range of the excitation angle θ_{C_prop} in the excitation portion in which the electrode finger is included.

As previously described, excitation portions with mutually different excitation angles θ_{C_prop} differ in terms of the separation between the reverse-velocity surfaces for the primary mode and spurious waves. According to the first example embodiment, however, the resonant frequency or anti-resonant frequency of the primary mode is the same or substantially the same in all of the excitation portions. According to the first example embodiment, the excitation portions in which individual electrode fingers are included differ from each other in the range of the excitation angle θ_{C_prop}. Consequently, for each of the portions in which individual electrode fingers are located, the frequency variation range of spurious waves excited in the portion differs. The spurious waves can thus be effectively dispersed. Therefore, spurious waves and transverse modes that are outside the pass band can be effectively reduced.

As described above, the phase velocity corresponds to the reciprocal of the reverse-velocity surface. Therefore, the relationship between the excitation angle θ_{C_prop} and the phase velocity is generally consistent with the reverse-velocity surface in the XY-plane of the piezoelectric substrate as illustrated in FIG. 15. It can be thus said that the function representing the curved shape of the electrode fingers is determined by the shape of the reverse-velocity surface in the XY-plane of the piezoelectric substrate. The phase velocity of acoustic waves has dependence on the excitation angle θ_{C_prop}.

According to the first example embodiment, the duty ratio, which affects frequency, is varied in accordance with the excitation angle θ_{C_prop}, so that acoustic waves excited at each excitation angle θ_{C_prop} have the same or substantially the same frequencies. The relationship between the excitation angle θ_{C_prop} and the duty ratio according to the first example embodiment is illustrated in FIG. 16. FIG. 16 also illustrates, as a second modification of the first example embodiment, an example in which the maximum value of the duty ratio differs from that according to the first example embodiment.

FIG. 16 illustrates, for the IDT electrode according to the first example embodiment and an IDT electrode according to the second modification thereof, the relationship between the absolute value |θ_{C_prop}| of the excitation angle, and the duty ratio.

According to the first example embodiment, the duty ratio has a maximum value when the excitation angle θ_{C_prop} is about 0°. That is, according to the first example embodiment, the reference line N is the straight line passing through the fixed point C, and the excitation portion with the highest duty ratio among all of the excitation portions. According to the first example embodiment, the duty ratio is, for example, about 0.5 when the excitation angle θ_{C_prop} is about 0°. The greater the absolute value |θ_{C_prop}| of the excitation angle, the lower the duty ratio. As a result, all of the excitation portions have the same or substantially the same resonant frequencies or anti-resonant frequencies.

According to the second modification as well, the greater the absolute value |θ_{C_prop}| of the excitation angle, the lower the duty ratio. According to the second example embodiment, for example, the duty ratio is about 0.634 when the excitation angle θ_{C_prop} is about 0°. According to the second modification as well, the resonant frequency or anti-resonant frequency is the same or substantially the same in all of the excitation portions. In addition, the second modification is similar in configuration to the first example embodiment except for the duty ratio. Therefore, the second modification makes it possible to reduce spurious waves, and improve the Q factor.

The relationship between the duty ratio and the frequency of each mode varies depending on the reverse-velocity surface of the piezoelectric substrate. Therefore, depending on the composition of the piezoelectric substrate or the configuration of components on the substrate, there may be cases where all of the excitation portions have the same or substantially the same resonant frequencies or anti-resonant frequencies when the duty ratio increases with increasing absolute value |θ_{C_prop}| of the excitation angle. In such cases, the reference line N is the straight line passing through the fixed point C, and the excitation portion with the lowest duty ratio among all of the excitation portions. A non-limiting example of such a case is an acoustic wave device in which an IDT electrode on a substrate made solely of rotated Y-cut −4° X-propagation LiNbO₃ is embedded in a thick SiO₂ film, for example. In another example, the duty ratio does not necessarily have a maximum or minimum value in the excitation portion having the excitation angle θ_{C_prop} of about 0° and through which the reference line N passes.

Returning now to FIG. 1, according to the first example embodiment, the first offset electrodes 18, and the second offset electrodes 19 each have a shape in plan view that corresponds to a circular arc defining the corresponding one of a plurality of concentric circles. The center of the circles each including the circular arc defining the shape of the corresponding one of the first offset electrodes 18 and the second offset electrodes 19 coincides with the fixed point C. The reflector electrode fingers 9c of the reflector 9A, and the reflector electrode fingers 9f of the reflector 9B each similarly have a shape in plan view that corresponds to a circular arc defining the corresponding one of a plurality of concentric circles. The center of the circles each including the circular arc defining the shape of the corresponding one of the reflector electrode fingers 9c and the reflector electrode fingers 9f coincides with the fixed point C. The above-described configuration, however, is not intended to be limiting.

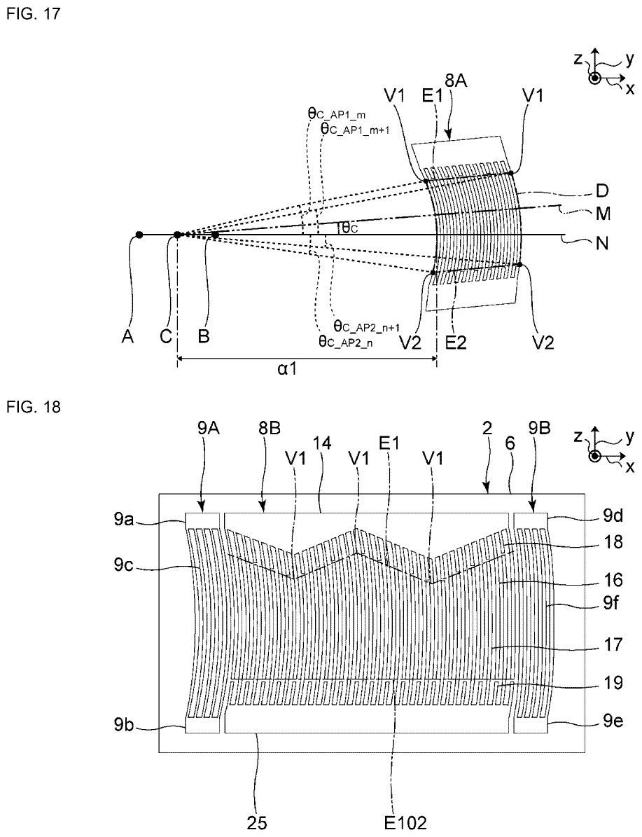

FIG. 17 is a schematic plan view, for explaining the configuration of an IDT electrode according to a third modification of the first example embodiment, of a segment of the IDT electrode.

In an IDT electrode 8A according to the third modification, the electrode fingers have a shape in plan view that includes the shape of an elliptical arc. Specifically, the electrode fingers each have a shape in plan view that corresponds to an elliptical arc defining the corresponding one of a plurality of ellipses with the same centroid. The midpoint of a focus A and a focus B is the fixed point C. In other words, the fixed point C is the centroid of the focus A and the focus B. It can be also said that the centroid of the focus A and the focus B is the centroid of an ellipse having the focus A and the focus B. The shape of the electrode fingers in plan view has an ellipticity α1/α2 other than about 1.

Similarly, the offset electrodes each have a shape in plan view that corresponds to an elliptical arc defining the corresponding one of a plurality of ellipses having the same centroid. The midpoint of the foci of the ellipses each including the elliptical arc defining the shape of the corresponding offset electrode coincides with the fixed point C. In other words, the centroid of the foci of these ellipses coincides with the fixed point C. Similarly, the reflector electrode fingers of each reflector have a shape in plan view that corresponds to an elliptical arc defining the corresponding one of a plurality of ellipses having the same centroid. The midpoint of the foci of the ellipses each including the elliptical arc defining the shape of the corresponding reflector electrode finger of each reflector coincides with the fixed point C. In other words, the centroid of the foci of these ellipses coincides with the fixed point C.

According to the third modification as well, as with the first example embodiment, the first envelope E1 and the second envelope E2 each include a portion extending at an inclination relative to the propagation axis, and include at least one bend. Therefore, the third modification makes it possible to reduce spurious waves, and improve the Q factor.

Returning now to FIG. 1, according to the first example embodiment, a dimension corresponding to the period of the wavy shape of the first envelope E1, and a dimension corresponding to the amplitude of the wavy shape of the first envelope E1 are constant. Specifically, the dimension corresponding to the period is the component of the distance, in the direction in which the propagation axis extends, between the bends V1 at the opposite end portions of an arrangement of three consecutive bends V1. The dimension corresponding to the amplitude is the component of the distance, in the direction orthogonal or substantially orthogonal to the propagation axis, between mutually adjacent bends V1. For the first envelope E1, at least one of the dimension corresponding to the period of the wavy shape, or the dimension corresponding to the amplitude of the wavy shape may not be constant. In this case, transverse modes can be effectively reduced.

As for envelope E2, the second the dimension corresponding to the period of the wavy shape, and the dimension corresponding to the amplitude of the wavy shape can be defined similarly to those of the first envelope E1. For the second envelope E2 as well, at least one of the dimension corresponding to the period of the wavy shape, or the dimension corresponding to the amplitude of the wavy shape may not be constant.

According to the first example embodiment, the dimension corresponding to the period of the wavy shape, and the dimension corresponding to the amplitude of the wavy shape are both the same or substantially the same between the first envelope E1 and the second envelope E2. Alternatively, however, at least one of the dimension corresponding to the period of the wavy shape, or the dimension corresponding to the amplitude of the wavy shape may be different between the first envelope E1 and the second envelope E2. In this case, transverse modes can be effectively reduced.

According to the first example embodiment, for each of the first envelope E1 and the second envelope E2, the absolute value of its inclination angle is constant. Alternatively, for each of the first envelope E1 and the second envelope E2, the absolute value of its inclination angle may not be constant.

According to example embodiments of the present invention, it may be sufficient that at least one of the first envelope E1 or the second envelope E2 includes bends. For example, according to a fourth modification of the first example embodiment in FIG. 18, of the first envelope E1 and the second envelope E102 of an IDT electrode 8B, only the first envelope E1 has a wavy shape. The second envelope E102 has a straight shape. A second busbar 25 has a straight shape in plan view in a portion near the second envelope E102. In this case as well, as with the first example embodiment, spurious waves can be reduced, and the Q factor can be improved.

As illustrated in FIG. 2, according to the first example embodiment, the piezoelectric substrate 2 is a multilayer substrate including the following components: the support substrate 4, the first layer 5a and the second layer 5b of the intermediate layer 5, and the piezoelectric layer 6. More specifically, the first layer 5a according to the first example embodiment is a high acoustic velocity film. A high acoustic velocity film is a film with a relatively high acoustic velocity. More specifically, the acoustic velocity f the bulk wave propagating through the high acoustic velocity film is higher than the acoustic velocity of the acoustic wave propagating through the piezoelectric layer 6. The second layer 5b is a low acoustic velocity film. A low acoustic velocity film is a film with a relatively low acoustic velocity. More specifically, the acoustic velocity of the bulk wave propagating through the low acoustic velocity film is lower than the acoustic velocity of the bulk wave propagating through the piezoelectric layer 6.

According to the first example embodiment, the high acoustic velocity film, the low acoustic velocity film, and the piezoelectric layer 6 are stacked in this order on the piezoelectric substrate 2. This makes it possible to effectively confine the acoustic wave energy toward the piezoelectric layer 6.

Examples of suitable materials for the high acoustic velocity film may include piezoelectrics such as aluminum nitride, lithium tantalate, lithium niobate, or quartz, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, diamond-like carbon (DLC), or diamond, semiconductors such as silicon, and materials including one or more of the above-described materials as major components. The spinel includes an aluminum compound including oxygen and at least one element selected from, for example, Mg, Fe, Zn, or Mn. Non-limiting examples of the spinel may include MgAl₂O₄, FeAl₂O₄, ZnAl₂O₄, or MnAl₂O₄. As used herein, the term major component refers to a component that accounts for more than about 50% by weight. A material defining the major component may be provided in one of the following states: monocrystal, polycrystal, and amorphous, or may be provided in a mixture of these states.

Examples of suitable materials for the low acoustic velocity film may include dielectrics such as glass, silicon oxide, silicon oxynitride, lithium oxide, tantalum oxide, or compounds of silicon oxide with added fluorine, carbon, or boron, and materials including one or more of the above-described materials as major components.

Non-limiting examples of suitable materials for the piezoelectric layer 6 may include lithium tantalate, lithium niobate, zinc oxide, aluminum nitride, quartz, or lead zirconate titanate (PZT). The piezoelectric layer 6 is preferably made of, for example, lithium tantalate or lithium niobate.

Examples of suitable materials for the support substrate 4 may include piezoelectrics such as aluminum nitride, lithium tantalate, lithium niobate, or quartz, ceramics such as alumina, sapphire, magnesia, silicon nitride, silicon carbide, zirconia, cordierite, mullite, steatite, or forsterite, dielectrics such as diamond or glass, semiconductors such as silicon, gallium nitride, or gallium arsenide, resin, and materials including one or more of the above-described materials as major components. It is preferable to use, for example, high-resistivity silicon for the support substrate 4. It is preferable for the material of the support substrate 4 to have a volume resistivity greater than or equal to about 1000 Ω·cm, for example.

A suitable material for the IDT electrode 8 may be, for example, at least one metal of Ti, Mo, Ru, W, Al, Pt, Ir, Cu, Cr, or Sc. A material the same as or similar to that used for the IDT electrode 8 may be used for each reflector as well. The IDT electrode 8 and each reflector may include a single metal film or a multilayer metal film.

According to the first example embodiment, the duty ratio is varied in accordance with the angle θ_{C} or the excitation angle θ_{C_prop} to make all of the excitation portions have the same or substantially the same resonant frequencies or anti-resonant frequencies. According to example embodiments of the present invention, there is no particular limitation on how parameters such as the duty ratio are set. Preferably, however, parameters that affect frequency, such as the duty ratio, the electrode finger pitch, the thickness of the electrode fingers, the thickness of the piezoelectric layer, and the thickness of the intermediate layer within the piezoelectric substrate, are varied in accordance with the angle θ_{C} or the excitation angle θ_{C_prop}. For a case where a dielectric film is disposed on the piezoelectric substrate so as to cover the IDT electrode, the thickness of the dielectric film may be varied in accordance with the angle θ_{C} or the excitation angle θ_{C_prop}. A plurality of parameters among the above-described parameters may be varied in accordance with the angle θ_{C} or the excitation angle θ_{C_prop}. It is preferable for at least one of these parameters to vary in accordance with the angle θ_{C} or the excitation angle θ_{C_prop}, so that all of the excitation portions have the same or substantially the same resonant frequencies or anti-resonant frequencies. This makes it possible to more reliably improve the resonance characteristics.

Similarly, as for the reflector 9A and the reflector 9B, parameters such as the duty ratio, the reflector electrode finger pitch, the thickness of the reflector electrode fingers, the thickness of the piezoelectric layer, and the thickness of the intermediate layer within the piezoelectric substrate, are preferably varied in accordance with the angle θ_{C} or the excitation angle θ_{C_prop}. For a case where a dielectric film is disposed on the piezoelectric substrate so as to cover the reflector 9A and the reflector 9B, the thickness of the dielectric film may be varied in accordance with the angle θ_{C} or the excitation angle θ_{C_prop}. A plurality of parameters among the above-described parameters may be varied in accordance with the angle θ_{C} or the excitation angle θ_{C_prop}. For example, a case may be assumed where the reflector 9A and the reflector 9B are portions of the IDT electrode 8. In this case, it is preferable for at least one of the above-described parameters to vary in accordance with the angle θ_{C} or the excitation angle θ_{C_prop}, so that all of the excitation portions have the same or substantially the same resonant frequencies or anti-resonant frequencies. This makes it possible to more reliably improve the resonance characteristics.

Each of the IDT electrode configurations according to the first example embodiment and its modifications is an illustrative example according to the present invention. According to example embodiments of the present invention, the electrode fingers of the IDT electrode, or the reflector electrode fingers of each reflector may have any curved shape in plan view. For example, the electrode fingers may have a shape for which a plurality of fixed points are defined. In this case, in the intersecting region, the electrode fingers may have, in plan view, a shape formed by connecting different curves with each other. Alternatively, in the intersecting region, the electrode fingers may include, in plan view, a straight shape in addition to a curved shape. The electrode fingers may include a plurality of inflection points, each of which is defined as the point at which different curves are connected with each other, or the point at which a curve and a straight line are connected with each other. The same as above also applies to the reflector electrode fingers.

A curve defining the shape of each of the electrode fingers and the reflector electrode fingers in plan view may have a shape formed by connecting minute straight lines. Alternatively, a curve defining the shape of each of the electrode fingers and the reflector electrode fingers in plan view need not necessarily be a smooth curve.

According to the first example embodiment, each of the electrode fingers has a width that varies continuously. Each electrode finger may, however, have a width that varies discontinuously. In this case, it may suffice, for example, that each electrode finger is substantially formed by connecting a plurality of portions, and at each connection of different portions, the connected portions each have a different width. The same as above applies to each reflector electrode finger.

According to example embodiments of the present invention, the reference line need not necessarily pass through the fixed point. The reference line may be defined individually for each of local regions on a curve defining the shape of each electrode finger in plan view. In this case, the reference line includes an origin other than the fixed point. It is preferable, however, that in the acoustic wave devices according to example embodiments of the present invention, even when a plurality of reference lines with different origins are to be defined, the reference lines extend parallel or substantially parallel to each other.

In the acoustic wave device 1, the reflector busbars 9a and 9b of the reflector 9A extend parallel or substantially parallel to the propagation axis. Similarly, the reflector busbars 9d and 9e of the reflector 9B extend parallel or substantially parallel to the propagation axis. Alternatively, however, the reflector busbars of each reflector may extend at an inclination relative to the propagation axis.

A second example embodiment and a third example embodiment of the present invention will now be described. In acoustic wave devices according to the second example embodiment and the third example embodiment, as with the first example embodiment, the first and second electrode fingers each have a shape in plan view that includes a curved portion in the intersecting region. The reflector electrode fingers each have a shape in plan view that includes a curved portion. The first envelope and the second envelope include a portion extending at an inclination relative to the propagation axis, and include at least one bend. This makes it possible to reduce spurious waves, and improve the Q factor.

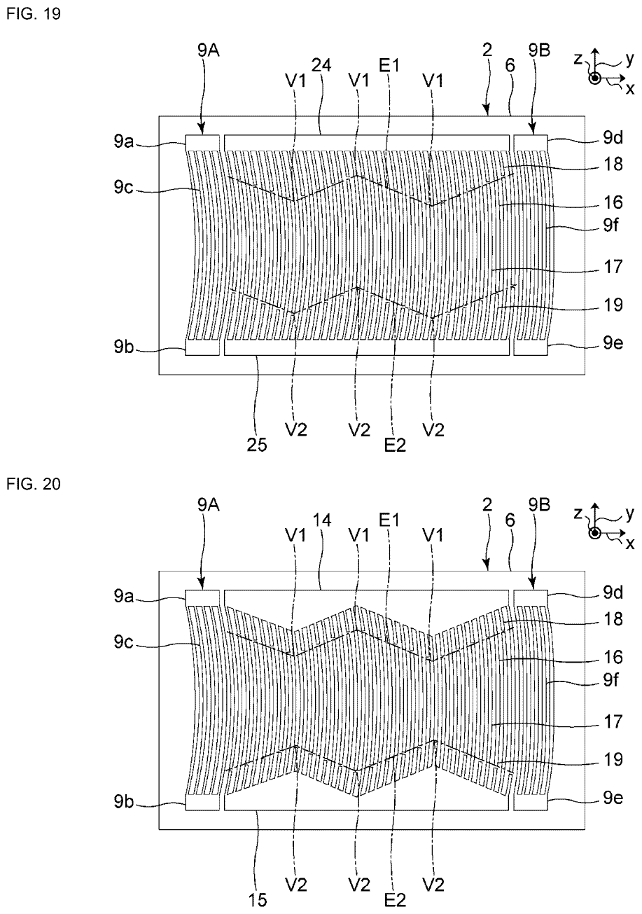

FIG. 19 is a schematic plan view of the acoustic wave device according to the second example embodiment.

The second example embodiment differs from the first example embodiment in the following respects. A first busbar 24 has a straight shape in plan view in a portion near the first envelope E1, and the second busbar 25 has a straight shape in plan view in a portion near the second envelope E2. The second example embodiment differs from the first example embodiment also in the following respects. The first offset electrodes 18 do not have a constant length, and the second offset electrodes 19 do not have a constant length. The acoustic wave device according to the second example embodiment is otherwise the same as or similar in configuration to the acoustic wave device 1 according to the first example embodiment.

According to the second example embodiment, the first busbar 24 has a straight shape in a portion connected with the proximal end portion of the first offset electrodes 18. In contrast, the first envelope E1 has a wavy shape. The first offset electrodes 18 thus do not have a constant length. This results in an enlarged region for reflecting the primary mode. As a result, leakage of the primary mode can be effectively reduced. Similarly, for the second offset electrodes 19 as well, leakage of the primary mode can be effectively reduced. Therefore, the resonant characteristics can be improved.

FIG. 20 is a schematic plan view of the acoustic wave device according to the third example embodiment.

The third example embodiment differs from the first example embodiment in that the first envelope E1 and the second envelope E2 are bent in opposite directions. The acoustic wave device according to the third example embodiment is otherwise the same as or similar in configuration to the acoustic wave device 1 according to the first example embodiment.

Specifically, the first envelope E1 includes a bend V1 where the first envelope E1 is bent to protrude toward the first busbar 14. The second envelope E2 includes a bend V2 where the second envelope E2 is bent to protrude toward the second busbar 15. These bends, that is, the bend V1 where the corresponding envelope is bent to protrude toward the first busbar 14, and the bend V2 where the corresponding envelope is bent to protrude toward the second busbar 15, are arranged in the direction orthogonal or substantially orthogonal to the propagation axis.

Further, the first envelope E1 includes a bend V1 where the first envelope E1 is bent to protrude toward the second busbar 15. The second envelope E2 includes a bend V2 where the second envelope E2 is bent to protrude toward the first busbar 14. These bends, that is, the bend V1 where the corresponding envelope is bent to protrude toward the second busbar 15, and the bend V2 where the corresponding envelope is bent to protrude toward the first busbar 14, are arranged in the direction orthogonal or substantially orthogonal to the propagation axis.

The frequencies at which transverse modes occur, and the intensities of transverse modes depend on the dimension of the intersecting region in the direction orthogonal or substantially orthogonal to the propagation axis. According to the third example embodiment, the dimension of the intersecting region in the direction orthogonal or substantially orthogonal to the propagation axis varies. This makes it possible to disperse the frequencies at which transverse modes occur. The intersecting region according to the third example embodiment can be divided into portions each having a different dimension in the direction orthogonal or substantially orthogonal to the propagation axis. Transverse modes occur in each of these portions. The transverse modes occurring in each individual portion are thus small in magnitude. As a result, the overall magnitude of the responses of transverse modes is small. Therefore, transverse modes can be effectively reduced.

An example of the first intersecting angle θ_{C_AP1_k} and the second intersecting angle θ_{C_AP2_k} according to the third example embodiment will now be described.

First intersecting angle θ_{C_AP1_1}: about 7.5°

First intersecting angle θ_{C_AP1_2}: about 3°

Second intersecting angle θ_{C_AP2_1}: about 7.5°

Second intersecting angle θ_{C_AP2_2}: about 3°

According to the first to third example embodiments, the duty ratio is adjusted to make all of the excitation portions have the same or substantially the same resonant frequencies or anti-resonant frequencies. Alternatively, however, the electrode finger pitch may be adjusted to make all of the excitation portions have the same or substantially the same resonant frequencies or anti-resonant frequencies. This example will now be described with reference to a fourth example embodiment of the present invention.

The fourth example embodiment differs from the first example embodiment in that, in the IDT electrode, the duty ratio is constant, and the electrode finger pitch is not constant. An acoustic wave device according to the fourth example embodiment is otherwise the same as or similar in configuration to the acoustic wave device 1 according to the first example embodiment.

As described above, in the IDT electrode, the duty ratio is constant. Specifically, the duty ratio is about 0.5, for example. According to the fourth example embodiment, the reference line N is the straight line passing through the excitation portion with the widest electrode finger pitch among all of the excitation portions. The greater the absolute value |θ_{C_prop}| of the excitation angle, the narrower the electrode finger pitch. As a result, all of the excitation portions have the same or substantially the same resonant frequencies or anti-resonant frequencies. A specific example of the relationship between the absolute value |θ_{C_prop}| of the excitation angle, and the electrode finger pitch is described below. Now, for example, the electrode finger pitch in the excitation portion where the excitation angle θ_{C_prop} is about 0° is defined as p0, the electrode finger pitch in a given excitation portion is defined as p1, and {(p1−p0)/p0}×100[%] is defined as a rate of change Δpitch [%] in electrode finger pitch.

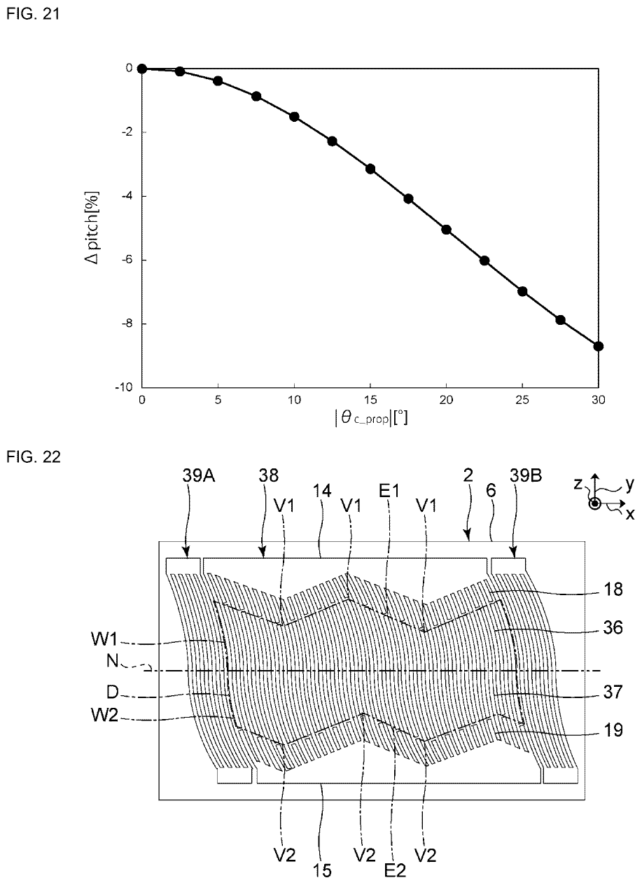

FIG. 21 illustrates, for the IDT electrode according to the fourth example embodiment, the relationship between the absolute angle |θ_{C_prop}| of the excitation angle, and the rate of change Δpitch in electrode finger pitch.

As illustrated in FIG. 21, according to the fourth example embodiment, Δpitch is about 0% for an excitation portion of the IDT electrode where the excitation angle θ_{C_prop} is about 0°. As the absolute value |θ_{C_prop}| of the excitation angle increases, Δpitch increases in the negative direction. That is, the greater the absolute value |θ_{C_prop}| of the excitation angle, the narrower the electrode finger pitch.

In the acoustic wave device according to the fourth example embodiment, as with the first example embodiment, the first electrode fingers and the second electrode fingers each have a shape in plan view that includes a curved portion in the intersecting region. The reflector electrode fingers each have a shape in plan view that includes a curved portion. The first envelope and the second envelope include a portion extending at an inclination relative to the propagation axis, and include at least one bend. This makes it possible to reduce spurious waves, and improve the Q factor.

The relationship between the electrode finger pitch and the frequency of each mode varies depending on the reverse-velocity surface of the piezoelectric substrate. Therefore, depending on the composition of the piezoelectric substrate or the configuration of components on the substrate, there may be cases where all of the excitation portions have the same or substantially the same resonant frequencies or anti-resonant frequencies when the electrode finger pitch increases with increasing absolute value |θ_{C_prop}| of the excitation angle. In such cases, the reference line N is the straight line passing through the fixed point C, and the excitation portion with the narrowest electrode finger pitch among all of the excitation portions. A non-limiting example of such a case is an acoustic wave device in which an IDT electrode on a substrate made solely of rotated Y-cut-4° X-propagation LiNbO₃ is embedded in a thick SiO₂ film. In another example, the electrode finger pitch does not necessarily have a maximum or minimum value in the excitation portion having the excitation angle θ_{C_prop} of about 0° and through which the reference line N passes.

FIG. 22 is a schematic plan view of an acoustic wave device according to a fifth example embodiment of the present invention.

The fifth example embodiment differs from the first example embodiment in the shape of a plurality of electrode fingers of an IDT electrode 38. The fifth example embodiment differs from the first example embodiment also in the shape of a plurality of reflector electrode fingers in each of a reflector 39A and a reflector 39B. The acoustic wave device according to the fifth example embodiment is otherwise the same as or similar in configuration to the acoustic wave device 1 according to the first example embodiment.

A plurality of first electrode fingers 36 and a plurality of second electrode fingers 37 each have, in plan view, a shape with an inflection point. As previously described, an inflection point is the point at which two different curves are connected, or at which a curve and a straight line are connected. When different curves are connected at an inflection point, the directions of curved shapes differ across the inflection point as the boundary. When it is stated herein that the directions of curved shapes differ, this refers to, for example, a situation where the curved shapes are curved in opposite directions. More specifically, for example, curved shapes are curved in opposite directions when one curved shape is curved convexly to the left in FIG. 22 and another curved shape is curved convexly to the right. According to the fifth example embodiment, two curved shapes are reversed with respect to each other across the inflection point as the boundary.

Specifically, the electrode fingers each have a shape in plan view defined by connecting two circular arcs. In plan view, one of the two circular arcs defining the shape of each of the electrode fingers is a circular arc that is a portion of the corresponding one of a plurality of concentric circles. The centers of the circles each including the circular arcs defining the shapes of the corresponding electrode fingers thus coincide with each other. The center of each of these circles can be defined as a first fixed point. In plan view, the other one of the two circular arcs defining the shape of each of the electrode fingers is similarly a circular arc that is a portion of the corresponding one of a plurality of concentric circles. The center of each of these circles can be defined as a second fixed point. According to the fifth example embodiment, two fixed points are defined in this way. The two fixed points are opposed to each other across the IDT electrode 38.

As described above, in plan view, the first electrode fingers 36 each have a shape in plan view that includes, in the intersecting region D, two curved portions differing in the direction in which the first electrode finger 36 is curved, and the second electrode fingers 37 each have a shape in plan view that includes, in the intersecting region D, two curved portions differing in the direction in which the second electrode finger 37 is curved. Further, in plan view, each of the electrode fingers may have a shape in plan view with at least one inflection point in the intersecting region D.

As with the electrode fingers of the IDT electrode 38, the reflector electrode fingers of the reflectors each have a shape in plan view that is defined by connecting two circular arcs. For each reflector electrode finger as well, the same fixed points as the fixed points defined for the electrode fingers of the IDT electrode 38 can be defined.

The intersecting region D includes a plurality of curved regions. Specifically, the curved regions include a first curved region W1, and a second curved region W2. The first curved region W1 includes the first envelope E1. The second curved region W2 includes the second envelope E2. In each curved region, the first electrode fingers 36 and the second electrode fingers 37 each have the shape of a single circular arc or elliptical arc in plan view. According to the fifth example embodiment, in each curved region, the electrode fingers have the shape of a single circular arc in plan view. The number of curved regions in the intersecting region D is not limited to two. For example, the intersecting region D may include three or more curved regions.

One of the two fixed points described above is a fixed point defined for the first curved region W1. The other fixed point is a fixed point defined for the second curved region W2.

According to the fifth example embodiment, a portion of each curved region that is located on a given straight line passing through a fixed point is defined as an excitation portion. A straight line extending parallel or substantially parallel to the propagation axis and passing through a fixed point is defined as the reference line N. According to the fifth example embodiment, two fixed points are located on a single reference line N. The boundary between the first curved region W1 and the second curved region W2 is the reference line N.

For each of the curved regions, the angle θ_{C} is defined as the angle between the reference line N, and a straight line passing through the fixed point and through an excitation portion of the curved region. The excitation angle θ_{C_prop} is defined as the angle between the reference line N and a direction, the direction being the direction of acoustic wave excitation at the point of intersection between each electrode finger and a straight line passing through the fixed point and through an excitation portion of the curved region. In this case, the electrode finger pitch is varied in accordance with the angle θ_{C} or the excitation angle θ_{C_prop} in each of the excitation portions to make all of the excitation portions of each curved region have the same or substantially the same resonant frequencies or anti-resonant frequencies.

For each of the curved regions, at least one of the duty ratio, the electrode finger pitch, or the thickness of each of the first electrode fingers 36 and the second electrode fingers 37 may be varied in accordance with the angle θ_{C} or the excitation angle θ_{C_prop} in each of the excitation portions of the curved region. Alternatively, for a case where a dielectric film is disposed on the piezoelectric substrate 2 so as to cover the IDT electrode 38, the thickness of the dielectric film may be varied in accordance with the angle θ_{c} or the excitation angle θ_{c_prop}. A plurality of parameters among the above-described parameters may be varied in accordance with the angle θ_{C} or the excitation angle θ_{C_prop}. It is preferable for at least one of these parameters to vary in accordance with the angle θ_{c} or the excitation angle θ_{c_prop} to make all of the excitation portions have the same or substantially the same resonant frequencies or anti-resonant frequencies. This makes it possible to more reliably improve the resonance characteristics.

In the acoustic wave device according to the fifth example embodiment, as with the first example embodiment, the first electrode fingers 36 and the second electrode fingers 37 each have a shape in plan view that includes a curved portion in the intersecting region D. The reflector electrode fingers each have a shape in plan view that includes a curved portion. The first envelope E1 and the second envelope E2 include a portion extending at an inclination relative to the propagation axis, and include at least one bend. This makes it possible to reduce spurious waves, and improve the Q factor.

According to the fifth example embodiment, the portion defined by the combination of the offset electrodes and the electrode fingers has, in the first and second curved regions W1 and W2 of the intersecting region D, a shape that is symmetric or substantially symmetric with respect to a point. In this case, each electrode finger includes a portion curved convexly toward the reflector 39A, and a portion curved convexly toward the reflector 39B. When the piezoelectric layer 6 is, for example, a monocrystalline film with material anisotropy, a spurious wave propagating toward the reflector 39A and a spurious wave propagating toward the reflector 39B may have opposite phase signs in some cases. In such cases, the spurious waves can be effectively reduced.

An example of the first intersecting angle θ_{C_AP1_k} and the second intersecting angle θ_{C_AP2_k} according to the third fifth will now be described.

First intersecting angle θ_{C_AP1_1}: about 10.5°

First intersecting angle θ_{C_AP1_2}: about 9°

Second intersecting angle θ_{C_AP2_1}; about 9°

Second intersecting angle θ_{C_AP2_2}; about 10.5°

According to the first to fifth example embodiments, the duty ratio or the electric finger pitch is adjusted to make all of the excitation portions have the same or substantially the same resonant frequencies or anti-resonant frequencies. Alternatively, however, the thickness of the electrode fingers may be adjusted to make all of the excitation portions have the same or substantially the same resonant frequencies or anti-resonant frequencies. This example will now be described with reference to a sixth example embodiment of the present invention.

The sixth example embodiment differs from the first example embodiment in that, in the IDT electrode, the duty ratio is constant, and the thickness of the electrode fingers is not constant. An acoustic wave device according to the sixth example embodiment is otherwise the same as or similar in configuration to the acoustic wave device 1 according to the first example embodiment.

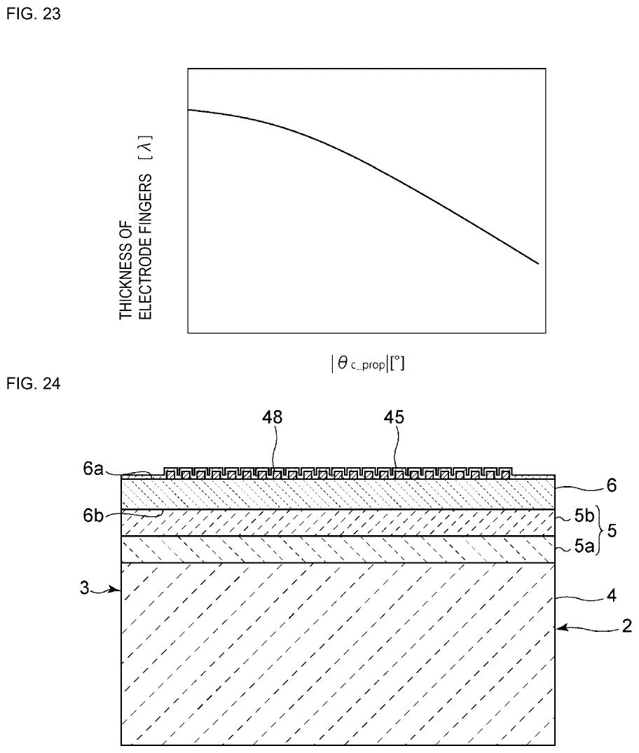

FIG. 23 illustrates, for an IDT electrode according to the sixth example embodiment, the relationship between the absolute angle |θ_{C_prop}| of the excitation angle, and the electrode finger thickness.

According to the sixth example embodiment, the reference line N is the straight line passing through the fixed point C, and the excitation portion with the thickest first and second electrode fingers among all of the excitation portions. As illustrated in FIG. 23, the greater the absolute value |θ_{C_prop}| of the excitation angle in the IDT electrode, the thinner the first and second electrode fingers. As a result, all of the excitation portions have the same or substantially the same resonant frequencies or anti-resonant frequencies.

In addition, in the acoustic wave device according to the sixth example embodiment, as with the first example embodiment, the first electrode fingers and the second electrode fingers each have a shape in plan view that includes a curved portion in the intersecting region. The reflector electrode fingers each have a shape in plan view that includes a curved portion. The first envelope and the second envelope include a portion extending at an inclination relative to the propagation axis, and include at least one bend. This makes it possible to reduce spurious waves, and improve the Q factor.

The relationship between the thickness of the first and second electrode fingers, and the frequency of each mode varies depending on the reverse-velocity surface of the piezoelectric substrate. Therefore, depending on the composition of the piezoelectric substrate or the configuration of components on the substrate, there may be cases where all of the excitation portions have the same or substantially the same resonant frequencies or anti-resonant frequencies when the thickness of the first and second electrode fingers increases with increasing absolute value |θ_{C_prop}| of the excitation angle. In such cases, the reference line N is the straight line passing through the fixed point C, and the excitation portion with the thinnest first and second electrode fingers among all of the excitation portions. A non-limiting example of such a case is an acoustic wave device in which an IDT electrode on a substrate made solely of rotated Y-cut −4° X-propagation LiNbO₃ is embedded in a thick SiO₂ film. In another example, the thickness of the first and second electrode fingers does not necessarily have a maximum or minimum value in the excitation portion having the excitation angle θ_{C_prop} of about 0° and through which the reference line N passes.

According to the first to sixth example embodiments, the configuration of the IDT electrode is adjusted to make all of the excitation portions have the same or substantially the same resonant frequencies or anti-resonant frequencies. Alternatively, however, the thickness of a dielectric film covering the IDT electrode may be adjusted to make all of the excitation portions have the same or substantially the same resonant frequencies or anti-resonant frequencies. This example will now be described with reference to a seventh example embodiment of the present invention and a modification thereof.

FIG. 24 is a schematic elevational cross-sectional view of an acoustic wave device according to the seventh example embodiment. FIG. 24 is a schematic cross-sectional view taken along the reference line N. The same applies to schematic elevational cross-sectional views other than FIG. 24.

The seventh example embodiment differs from the first example embodiment in that, in an IDT electrode 48, the duty ratio is constant. The seventh example embodiment differs from the first example embodiment also in that a dielectric film 45 is disposed on the piezoelectric layer 6 so as to cover the IDT electrode 48. The acoustic wave device according to the seventh example embodiment is otherwise the same or similar in configuration to the acoustic wave device 1 according to the first example embodiment.

According to the seventh example embodiment, a transversal wave that propagates through the dielectric film 45 has an acoustic velocity higher than the acoustic velocity of the primary mode that propagates through the dielectric film 45. The dielectric film 45 has a thickness that varies with the excitation angle θ_{C_prop} in an excitation portion of the IDT electrode 48 that is covered by the dielectric film 45.

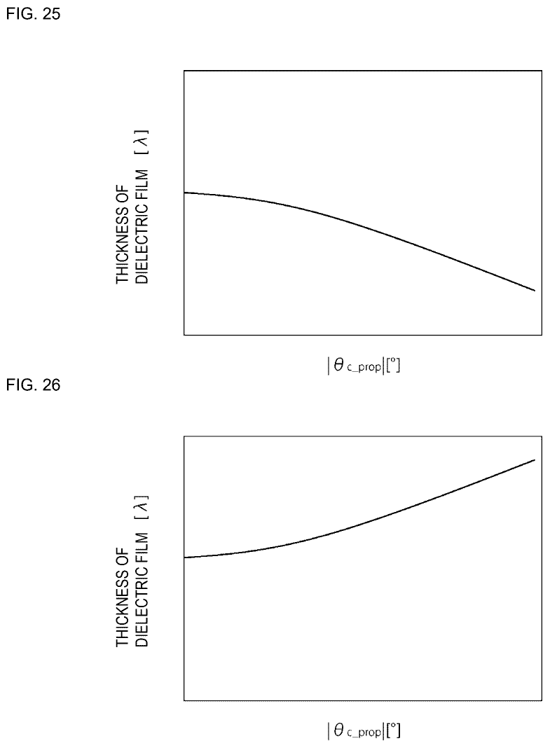

FIG. 25 illustrates, in accordance with the seventh example embodiment, the relationship between the absolute angle |θ_{C_prop}| of the excitation angle in an excitation portion of the IDT electrode that is covered by the dielectric film, and the thickness of the dielectric film in the excitation portion.

According to the seventh example embodiment, the reference line N is the straight line passing through the fixed point C, and the excitation portion where, among all of the excitation portions, the thickest portion of the dielectric film 45 is located. As illustrated in FIG. 25, according to the seventh example embodiment, the greater the absolute value |θ_{C_prop}| of the excitation angle in an excitation portion of the IDT electrode 48 that is covered by the dielectric film 45, the thinner the dielectric film 45. As a result, all of the excitation portions have the same or substantially the same resonant frequency or anti-resonant frequency.

In addition, according to the seventh example embodiment, as with the first example embodiment, the first electrode fingers and the second electrode fingers each have a shape in plan view that includes a curved portion in the intersecting region. The reflector electrode fingers each have a shape in plan view that includes a curved portion. The first envelope and the second envelope include a portion extending at an inclination relative to the propagation axis, and include at least one bend. This makes it possible to reduce spurious waves, and improve the Q factor.

According to the seventh example embodiment, a transversal wave that propagates through the dielectric film 45 has an acoustic velocity lower than the acoustic velocity of the primary mode that propagates through the dielectric film 45. However, the relationship between the acoustic velocities of waves propagating through the dielectric film is not limited to the above-described relationship. A modification of the seventh example embodiment will now be described. The modification differs from the seventh example embodiment only in the acoustic velocity of a transversal wave propagating through the dielectric film, and the manner in which the thickness of the dielectric film varies.

According to the modification of the seventh example embodiment, a transversal wave that propagates through the dielectric film has an acoustic velocity higher than the acoustic velocity of the primary mode that propagates through the dielectric film. According to the modification, the relationship between the absolute angle |θ_{C_prop}| of the excitation angle in an excitation portion of the IDT electrode that is covered by the dielectric film, and the thickness of the dielectric film in the excitation portion is as illustrated in FIG. 26. More specifically, according to the modification, the reference line N is the straight line passing through the fixed point C, and through the excitation portion where, among all of the excitation portions, the thinnest part of the dielectric film is located. The greater the absolute value |θ_{C_prop}| of the excitation angle in an excitation portion of the IDT electrode that is covered by the dielectric film, the thicker the dielectric film. As a result, all of the excitation portions have the same or substantially resonant frequencies or anti-resonant frequencies. In addition, as with the seventh example embodiment, the modification makes it possible to reduce spurious waves, and improve the Q factor.

Depending on the composition of the piezoelectric substrate or other factors, the thickness of the portion of the dielectric film that covers an excitation portion does not necessarily become maximum or minimum at the location through which the reference line N passes.

The multilayer structure of the piezoelectric substrate is not limited to that illustrated in FIG. 2. An example in which an acoustic wave device includes a piezoelectric substrate different from that according to the first example embodiment will now be described with reference to an eighth example embodiment of the present invention.

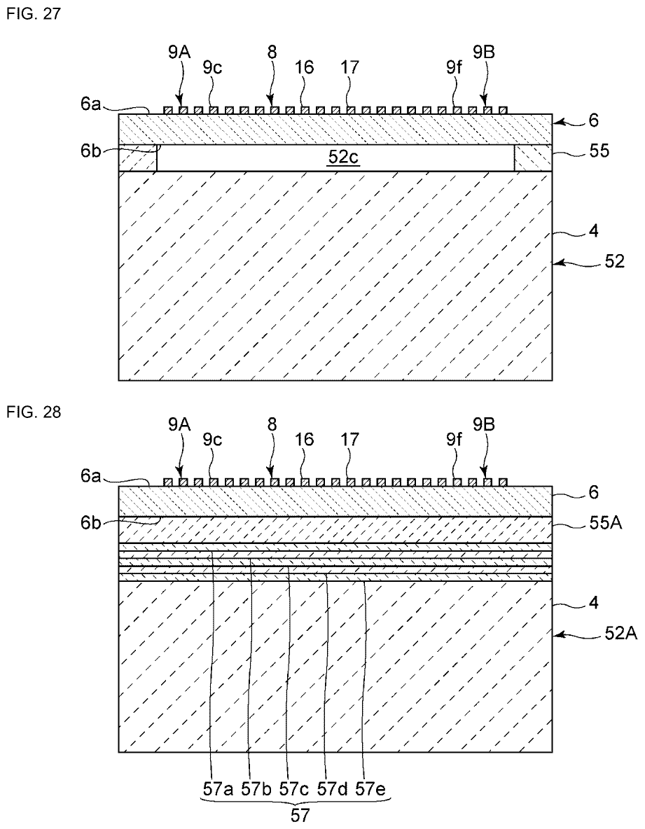

FIG. 27 is a schematic elevational cross-sectional view of an acoustic wave device according to the eighth example embodiment.

The eighth example embodiment differs from the first example embodiment in the multilayer structure of a piezoelectric substrate 52. The acoustic wave device according to the eighth example embodiment is otherwise the same or similar in configuration to the acoustic wave device 1 according to the first example embodiment.

The piezoelectric substrate 52 includes the support substrate 4, an intermediate layer 55, and the piezoelectric layer 6. The intermediate layer 55 is disposed on the support substrate 4. The piezoelectric layer 6 is disposed on the intermediate layer 55. According to the eighth example embodiment, the intermediate layer 55 has a frame shape. That is, the intermediate layer 55 includes a through-hole. The support substrate 4 covers one side of the through-hole of the intermediate layer 55. The piezoelectric layer 6 covers the other side of the through-hole of the intermediate layer 55. The piezoelectric substrate 52 thus includes a hollow 52c defined therein. A portion of the piezoelectric layer 6, and a portion of the support substrate 4 face each other across the hollow 52c.

According to the eighth example embodiment, the primary mode can be reflected toward the piezoelectric layer 6. This makes it possible to effectively confine the acoustic wave energy toward the piezoelectric layer 6. In addition, as with the first example embodiment, this also makes it possible to reduce spurious waves, and improve the Q factor.

A first modification and a second modification of the eighth example embodiment will now be described. These modifications differ from the eighth example embodiment only in the multilayer structure of the piezoelectric substrate. As with the eighth example embodiment, the first modification and the second modification make it possible to reduce spurious waves, and improve the Q factor. These modifications further make it possible to effectively confine the acoustic wave energy toward the piezoelectric layer 6.

According to the first modification in FIG. 28, a piezoelectric substrate 52A includes the support substrate 4, an acoustic reflection film 57, an intermediate layer 55A, and the piezoelectric layer 6. The acoustic reflection film 57 is disposed on the support substrate 4. The intermediate layer 55A is disposed on the acoustic reflection film 57. The piezoelectric layer 6 is disposed on the intermediate layer 55A. The intermediate layer 55A is a low acoustic velocity film.

The acoustic reflection film 57 is a multilayer body including a plurality of acoustic impedance layers. Specifically, the acoustic reflection film 57 includes a plurality of low acoustic impedance layers, and a plurality of high acoustic impedance layers. The high acoustic impedance layers are layers with relatively high acoustic impedance. More specifically, the high acoustic impedance layers of the acoustic reflection film 57 include a high acoustic impedance layer 57a, a high acoustic impedance layer 57c, and a high acoustic impedance layer 57e. The low acoustic impedance layers are layers with relatively low acoustic impedance. More specifically, the low acoustic impedance layers of the acoustic reflection film 57 include a low acoustic impedance layer 57b, and a low acoustic impedance layer 57d. The low acoustic impedance layers and the high acoustic impedance layers are stacked alternately. The high acoustic impedance layer 57a is the layer of the acoustic reflection film 57 that is located closest to the piezoelectric layer 6.

The acoustic reflection film 57 includes two low acoustic impedance layers, and three high acoustic impedance layers. It may suffice, however, that the acoustic reflection film 57 includes at least one low acoustic impedance layer, and at least one high acoustic impedance layer.

Examples of suitable materials for the low acoustic impedance layers may include silicon oxide and aluminum. Examples of suitable materials for the high acoustic impedance layers may include metals such as platinum or tungsten, and dielectrics such as aluminum nitride or silicon nitride. The intermediate layer 55A may be made of the same material as the material of the low acoustic impedance layers.

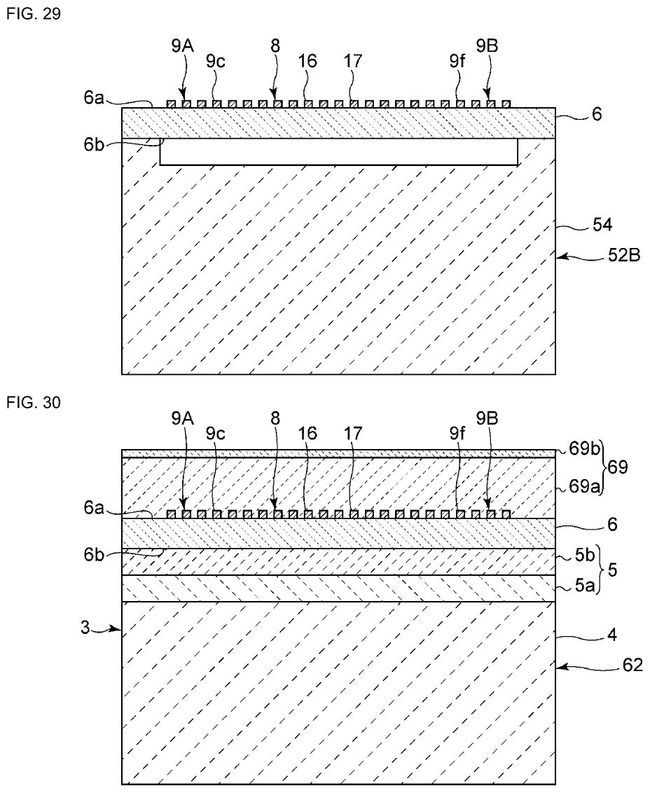

According to the second modification in FIG. 29, a piezoelectric substrate 52B includes a support substrate 54, and the piezoelectric layer 6. The piezoelectric layer 6 is disposed directly on the support substrate 54. More specifically, the support substrate 54 includes a recess. The piezoelectric layer 6 is disposed on the support substrate 54 so as to cover the recess. The piezoelectric substrate 52B thus includes a hollow defined therein. The hollow overlaps at least a portion of the IDT electrode 8 in plan view.

FIG. 30 is a schematic elevational cross-sectional view of an acoustic wave device according to a ninth example embodiment of the present invention.

The ninth example embodiment differs from the first example embodiment in that the IDT electrode 8 is embedded in a protective film. The acoustic wave device according to the ninth example embodiment is otherwise the same or similar in configuration to the acoustic wave device 1 according to the first example embodiment.

Specifically, a protective film 69 is disposed over the piezoelectric layer 6 so as to cover the IDT electrode 8. The protective film 69 has a thickness greater than the thickness of the IDT electrode 8. The IDT electrode 8 is embedded in the protective film 69. This helps to reduce damage to the IDT electrode 8.

The protective film 69 includes a first layer 69a, and a second layer 69b. The IDT electrode 8 is embedded in the first layer 69a. The second layer 69b is disposed on the first layer 69a. This allows the protective film 69 to provide a plurality of advantageous effects. Specifically, according to the ninth example embodiment, for example, silicon oxide is used as the material for the first layer 69a. This allows the temperature coefficient of frequency (TCF) of the acoustic wave device to have a small absolute value. Therefore, the temperature characteristics of the acoustic wave device can be improved. Silicon nitride, for example, is used for the second layer 69b. This makes it possible to improve moisture resistance.

In addition, in the acoustic wave device according to the ninth example embodiment, as with the first example embodiment, the first electrode fingers 16 and the second electrode fingers 17 each have a shape in plan view that includes a curved portion in the intersecting region. The reflector electrode fingers each have a shape in plan view that includes a curved portion. The first envelope and the second envelope include a portion extending at an inclination relative to the propagation axis, and include at least one bend. This makes it possible to reduce spurious waves, and improve the Q factor.

The respective materials of the first layer 69a and the second layer 69b are not limited to those described above. The protective film 69 may include a single layer, or may be a multilayer body including three or more layers.

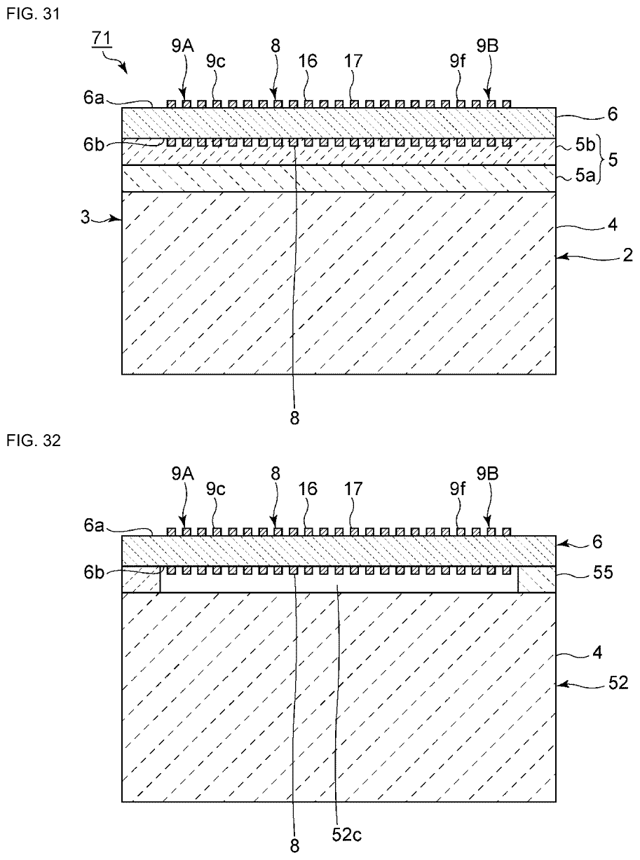

FIG. 31 is a schematic elevational cross-sectional view of an acoustic wave device according to a tenth example embodiment of the present invention.

The tenth example embodiment differs from the first example embodiment in that the IDT electrode 8 is disposed on both the first and second major surfaces 6a and 6b of the piezoelectric layer 6. The IDT electrode 8 on the second major surface 6b is embedded in the second layer 5b of the intermediate layer 5. An acoustic wave device 71 according to the tenth example embodiment is otherwise the same or similar in configuration to the acoustic wave device 1 according to the first example embodiment.

The IDT electrode 8 on the first major surface 6a of the piezoelectric layer 6, and the IDT electrode 8 on the second major surface 6b are opposed to each other across the piezoelectric layer 6. In the acoustic wave device according to the tenth example embodiment, as with the first example embodiment, the first electrode fingers 16 and the second electrode fingers 17 each have a shape in plan view that includes a curved portion in the intersecting region. The reflector electrode fingers each have a shape in plan view that includes a curved portion. The first envelope and the second envelope include a portion extending at an inclination relative to the propagation axis, and include at least one bend. This makes it possible to reduce spurious waves, and improve the Q factor.

The IDT electrode 8 on the first major surface 6a of the piezoelectric layer 6, and the IDT electrode 8 on the second major surface 6b may, for example, differ from each other in design parameters.

First to third modifications of the tenth example embodiment will now be described, which differ from the tenth example embodiment in only at least one of the configuration of the electrodes on the second major surface of the piezoelectric layer, or the multilayer structure of the piezoelectric substrate. As with the tenth example embodiment, the first to third modifications make it possible to reduce spurious waves, and improve the Q factor.

According to the first modification in FIG. 32, the piezoelectric substrate 52 is the same or similar in configuration to that according to the eighth example embodiment. Specifically, the piezoelectric substrate 52 includes the support substrate 4, the intermediate layer 55, and the piezoelectric layer 6. The IDT electrode 8 on the second major surface 6b of the piezoelectric layer 6 is located within the hollow 52c.

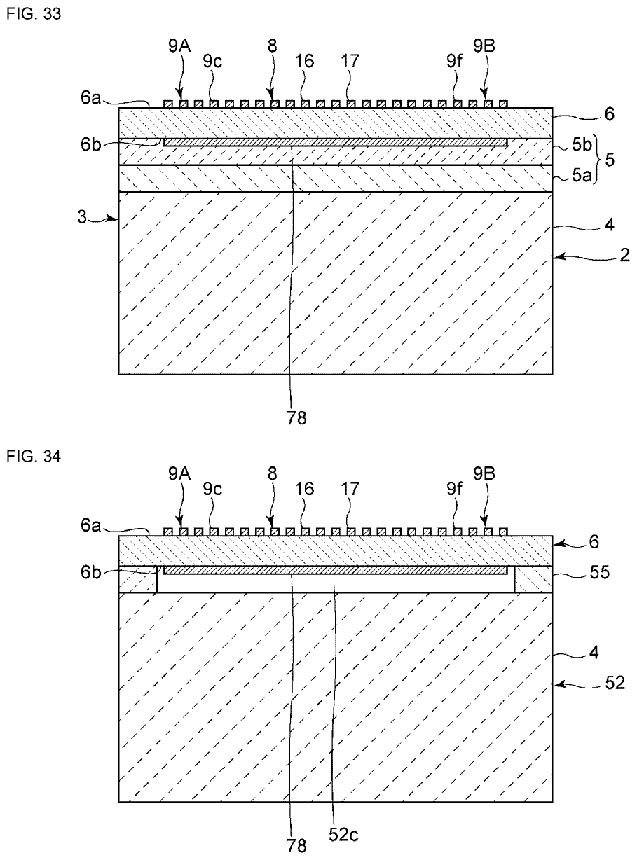

According to the second modification in FIG. 33, a plate-shaped electrode 78 is disposed on the second major surface 6b of the piezoelectric layer 6. The electrode 78 are embedded in the second layer 5b. The IDT electrode 8 and the electrode 78 are opposed to each other across the piezoelectric layer 6.

According to the third modification in FIG. 34, the piezoelectric substrate 52 is the same or similar in configuration to that according to the first modification, and the electrode 78 the same as or similar to that according to the second modification is disposed on the second major surface 6b of the piezoelectric layer 6. The electrode 78 is located within the hollow 52c. The IDT electrode 8 and the electrode 78 are opposed to each other across the piezoelectric layer 6.

The acoustic wave devices according to example embodiments of the present invention can be used in, for example, a filter device. This example will now be explained.

FIG. 35 is a circuit diagram of a filter device according to an eleventh example embodiment of the present invention.

A filter device 80 according to the eleventh example embodiment is a ladder filter, for example. The filter device 80 includes a first signal terminal 82, a second signal terminal 83, a plurality of series resonators, and a plurality of shunt resonators. In the filter device 80, all of the series resonators and all of the shunt resonators are acoustic wave resonators. Further, all of the series resonators and all of the shunt resonators are each an acoustic wave device according to an example embodiment of the present invention. It may suffice, however, that at least one of the acoustic wave resonators of the filter device 80 is an acoustic wave device according to an example embodiment of the present invention.

The first signal terminal 82 is an antenna terminal. The antenna terminal is connected to an antenna. However, the first signal terminal 82 need not necessarily be an antenna terminal. The first signal terminal 82 and the second signal terminal 83 may be, for example, electrode pads or as wiring.

The series resonators according to the eleventh example embodiment specifically include a series resonator S1, a series resonator S2, and a series resonator S3. The series resonators are connected in series with each other between the first signal terminal 82 and the second signal terminal 83. The shunt resonators are specifically a shunt resonator P1, and a shunt resonator P2. The shunt resonator P1 is connected between the node of the series resonators S1 and S2 and the ground potential. The shunt resonator P2 is connected between the node of the series resonators S2 and S3 and the ground potential. The circuit configuration of the filter device 80 is not limited to the above. The filter device 80 may include, for example, a longitudinally coupled resonator acoustic wave filter.

The acoustic wave resonators of the filter device 80 are each an acoustic wave device according to an example embodiment of the present invention. Therefore, the acoustic wave resonators of the filter device 80 make it possible to reduce spurious waves, and improve the Q factor.

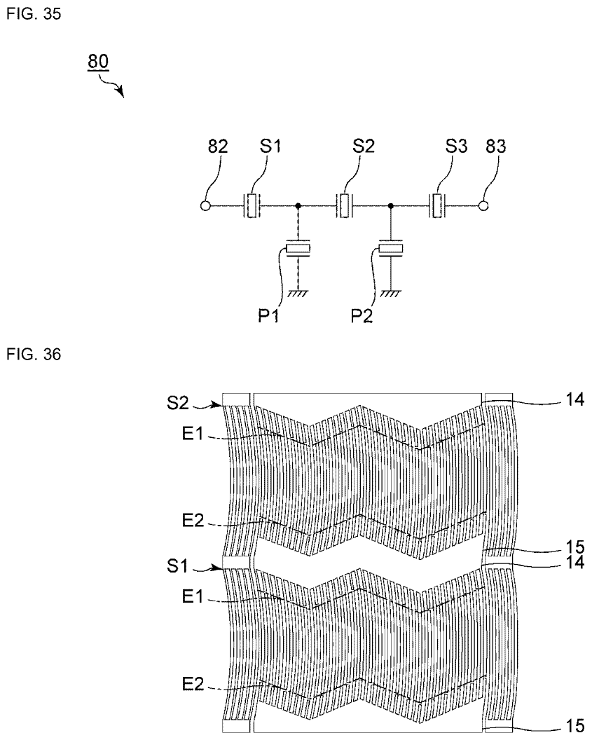

According to the eleventh example embodiment, each of the series resonator S1 and the series resonator S2 is, for example, the acoustic wave device 1 according to the first example embodiment. As illustrated in FIG. 36, the first busbar 14 of the series resonator S1, and the second busbar 15 of the series resonator S2 are connected with each other. Alternatively, however, the respective first busbars 14 of these series resonators may be connected with each other, or the respective second busbars 15 of these series resonators may be connected with each other.

The combination of the shapes of two mutually connected busbars among the respective busbars of the series resonators S1 and S2 is such that the shapes of both of these busbars near the corresponding envelopes are wavy. The combination of the shapes of two mutually unconnected busbars among the respective busbars of the series resonators S1 and S2 is also such that the shapes of both of these busbars near the corresponding envelopes are wavy. The combination of the shapes of two envelopes near two corresponding mutually connected busbars is such that the shapes of both of these envelopes are wavy. The combination of the shapes of two envelopes near two corresponding mutually unconnected busbars is also such that the shapes of both of these envelopes are wavy. The above-described configurations, however, are not intended to be limiting.

First to third modifications of the eleventh example embodiment will now be described, which differ from the eleventh example embodiment only in the combination of mutually connected series resonators. As with the eleventh example embodiment, the first to third modifications make it possible for the acoustic wave resonators of the filter device to reduce spurious waves, and improve the Q factor.

According to the first modification in FIG. 37, two acoustic wave devices according to the second example embodiment are connected with each other. The first busbar 24 of one of the acoustic wave devices, and the second busbar 25 of the other acoustic wave device are connected with each other.

The combination of the shapes of two mutually connected busbars is such that the shapes of both of these busbars near the corresponding envelopes are straight. The combination of the shapes of two mutually unconnected busbars is such that the shapes of both of these busbars near the corresponding envelopes are straight. The combination of the shapes of two envelopes near two corresponding mutually connected busbars is such that the shapes of both of these envelopes are wavy. The combination of the shapes of two envelopes near two corresponding mutually unconnected busbars is also such that the shapes of both of these envelopes are wavy.

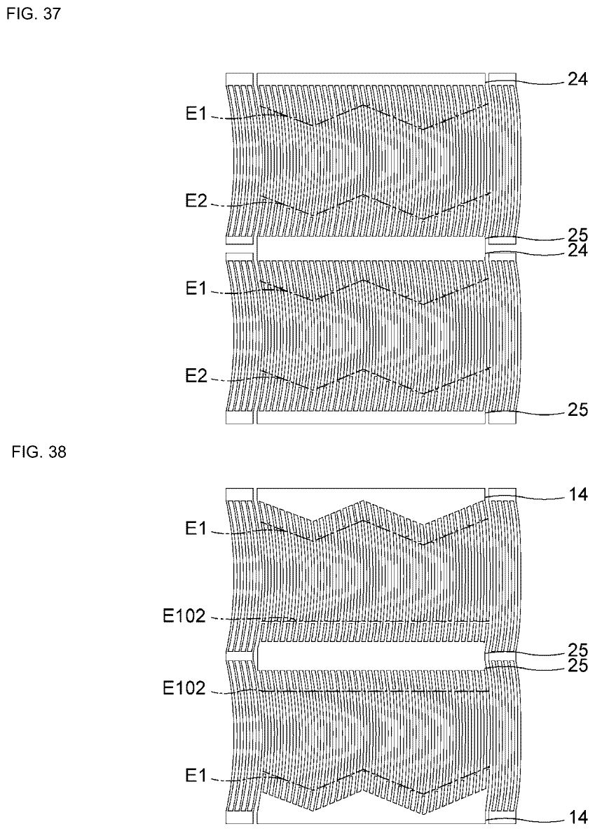

According to the second modification in FIG. 38, two acoustic wave devices according to the fourth modification of the first example embodiment are connected with each other. The second busbar 25 of one of the acoustic wave devices, and the second busbar 25 of the other acoustic wave device are connected with each other. In one of the acoustic wave devices, the electrode fingers and the reflector electrode fingers are curved in a direction opposite to the direction according to the example in FIG. 18.

The combination of the shapes of two mutually connected busbars is such that the shapes of both of these busbars near the corresponding envelopes are straight. The combination of the shapes of two mutually unconnected busbars is such that the shapes of both of these busbars near the corresponding envelopes are wavy. The combination of the shapes of two envelopes near two corresponding mutually connected busbars is such that the shapes of both of these envelopes are straight. The combination of the shapes of two envelopes near two corresponding mutually unconnected busbars is such that the shapes of both of these envelopes are wavy.

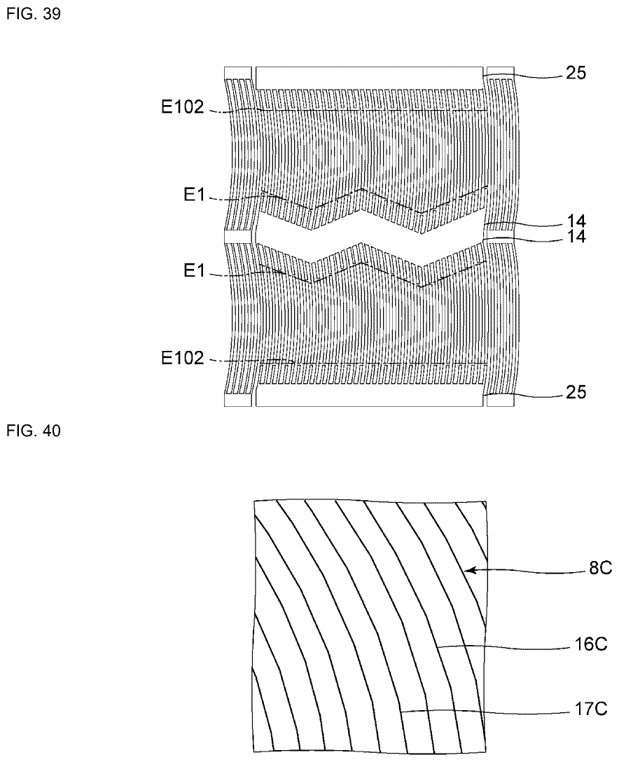

According to the third modification in FIG. 39, two acoustic wave devices according to the fourth modification of the first example embodiment are connected with each other. The first busbar 14 of one of the acoustic wave devices, and the first busbar 14 of the other acoustic wave device are connected with each other. In one of the acoustic wave devices, the electrode fingers and the reflector electrode fingers are curved in a direction opposite to the direction according to the example in FIG. 18.

The combination of the shapes of two mutually connected busbars is such that the shapes of both of these busbars near the corresponding envelopes are wavy. The combination of the shapes of two mutually unconnected busbars is such that the shapes of both of these busbars near the corresponding envelopes are straight. The combination of the shapes of two envelopes near two corresponding mutually connected busbars is such that the shapes of both of these envelopes are wavy. The combination of the shapes of two envelopes near two corresponding mutually unconnected busbars is such that the shapes of both of these envelopes are straight.

According to the second modification and the third modification, the dimension of the intersecting region in the direction orthogonal or substantially orthogonal to the propagation axis varies. This makes it possible to disperse the frequencies at which transverse modes occur. Therefore, transverse modes can be effectively reduced.

As illustrated in FIGS. 36 to 39, for the filter device, the design flexibility of acoustic wave devices can be improved. In addition, for acoustic wave resonators, spurious waves can be reduced, and the Q factor can be improved.

Although series resonators are connected to each other in the above-described example, a series resonator and a shunt resonator may be connected to each other in a manner the same as or similar to that illustrated in FIGS. 36 to 39.

The two connected acoustic wave resonators in the above-described example have the same or substantially the same capacitance, the same or substantially the same dimension of the intersecting region in the direction orthogonal or substantially orthogonal to the propagation axis, and the same number of electrode finger pairs. This, however, is not intended to be limiting. Two connected acoustic wave resonators need not necessarily have the same or substantially the same capacitance, the same or substantially the same dimension of the intersecting region in the direction orthogonal or substantially orthogonal to the propagation axis, and the same number of electrode finger pairs. Alternatively, the two acoustic wave resonators may differ in the curved shape of electrode fingers in plan view, or the design of electrode fingers. When three or more acoustic wave resonators are to be connected, the combination of the shapes of their busbars and the combination of the shapes of their envelopes may be the same as or similar to those exemplified above. For mutually connected acoustic wave resonators, the busbar to be connected may be a single busbar. Between two acoustic wave resonators to be connected, the combination of the shape of the first envelope and the shape of the second envelope may be the same or different. If two connected acoustic wave resonators differ in the combination of the shape of the first envelope and the shape of the second envelope, the difference may be provided by means of, for example, a configuration in which an envelope has a shape defined by connecting the bends by a curve, and a configuration in which an envelope has a shape defined by connecting the bends by a straight line.

In each of the acoustic wave devices according to the above-described example embodiments, the curve defining the shape of the electrode fingers in plan view is a smooth curve. In another example, the curve defining the shape of the electrode fingers in plan view may have a shape defined by connecting minute straight lines. In another example, the curve defining the shape of the electrode fingers in plan view may have a shape defined by connecting a plurality of vertexes by a curve. In still another example, the curve defining the shape of the electrode fingers in plan view need not necessarily be a smooth curve. This example will now be described with reference to a fifth modification of the first example embodiment.

An IDT electrode 8C according to the fifth modification is illustrated in enlarged view in FIG. 40. The curve defining the shape of first electrode fingers 16C in plan view is not a smooth curve. Specifically, the first electrode fingers 16C each have a shape in plan view that is defined by connecting straight lines. The straight lines defining the above-described shape are not minute straight lines. More specifically, the straight lines defining the above-described shape each have a length on the order of several percent of the total length of the first electrode finger 16C. It is to be noted, however, that the connected straight lines defining the above-described shape define a large angle with each other that is, for example, greater than or equal to about 160° and less than about 180°. Each first electrode finger 16C thus has a shape in plan view that can be approximated by a curve.

Each second electrode finger 17C also has a shape in plan view the same as or similar to the shape of each first electrode finger 16C in plan view. As with the first example embodiment, the fifth modification also makes it possible to reduce spurious waves, and improve the Q factor.

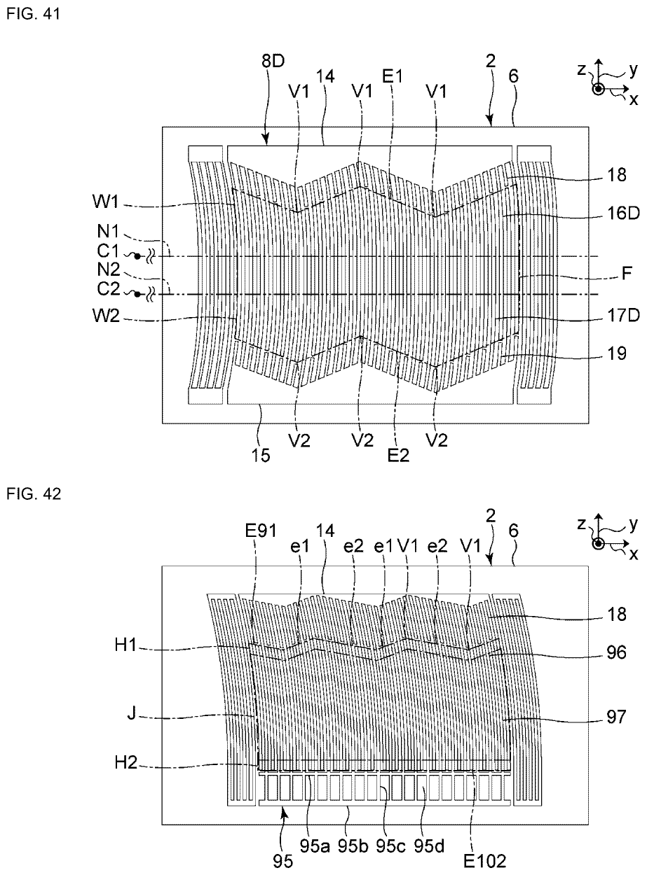

Alternatively, as described above, in the intersecting region, the first electrode fingers and the second electrode fingers may have a shape in plan view that includes a straight shape. According to a sixth modification of the first example embodiment in FIG. 41, the intersecting region includes a straight region F, and the first curved region W1 and the second curved region W2.

In the straight region F, first electrode fingers 16D and second electrode fingers 17D have a straight shape in plan view. The first curved region W1 and the second curved region W2 are opposed to each other across the straight region F. The first curved region W1 includes the first envelope E1. The second curved region W2 includes the second envelope E2. Each electrode finger includes two inflection points. According to the sixth modification, an inflection point is the point at which a curve and a straight line are connected.

An extended line of the boundary line between the straight region F and the first curved region W1 passes through a fixed point C1. A straight line including the boundary line and the extended line of the boundary line is a reference line N1 for the first curved region W1. In the first curved region W1, the angle θ_{C} is the angle between the reference line N1, and a straight line passing through the fixed point C1 and through an excitation portion of the first curved region W1. According to the sixth modification, θ_{C}=θ_{C_prop} in the first curved region W1.

An extended line of the boundary line between the straight region F and the second curved region W2 passes through a fixed point C2. A straight line including the boundary line and the extended line of the boundary line is a reference line N2 for the second curved region W2. In the second curved region W2, the angle θ_{C} is the angle between the reference line N2, and a straight line passing through the fixed point C2 and through an excitation portion of the second curved region W2. According to the sixth modification, θ_{C}=θ_{C_prop} in the second curved region W2.

In the straight region F, the excitation angle is constant. More specifically, at the boundary between the straight region F and the first curved region W1, the excitation angle θ_{C_prop} is about 0°. Similarly, at the boundary between the straight region F and the second curved region W2, the excitation angle θ_{C_prop} is about 0°. Therefore, the excitation angle of each excitation portion in the straight region F corresponds to about 0°. The excitation angle of each excitation portion in the straight region F need not necessarily be 0°.

According to the sixth modification, in the entire straight region F, the X-propagation direction in which the propagation axis of the piezoelectric layer 6 extends, and the direction in which the electrode fingers extend are orthogonal or substantially orthogonal to each other. The straight region F is thus a stable region relative to the propagation axis. The presence of the straight region F in the intersecting region makes it possible to, for an IDT electrode 8D as a whole, reduce variation of the propagation direction, and achieve stable acoustic wave propagation.

In addition, as with the first example embodiment, the sixth modification makes it possible to reduce spurious waves, and improve the Q factor.

The intersecting region according to an example embodiment of the present invention includes a pair of edge regions, and a central region. The edge regions are opposed to each other across the central region. One of the edge portions includes the first envelope. The other edge region includes the second envelope. A low acoustic velocity region may be provided in at least one of the pair of edge regions. The low acoustic velocity region is a region with an acoustic velocity lower than the acoustic velocity in the central region.

The low acoustic velocity region may be provided by, for example, making the duty ratio in the edge regions greater than the duty ratio in the central region. In this case, each electrode finger has a greater width in the edge regions than in the central region. The width of an electrode finger is the dimension of the electrode finger in a normal direction, which is the direction normal to the electrode finger. Accordingly, in each curved region, the normal direction, which defines and functions as the reference for the electrode finger width, differs for each portion of the curved region.

Alternatively, the low acoustic velocity region may be provided by stacking an electrode finger and a mass addition film in the edge regions. At the location where the electrode finger and the mass addition film are stacked, the piezoelectric layer, the electrode finger, and the mass addition film may be stacked in this order. At the location, the piezoelectric layer, the mass addition film, and the electrode finger may be stacked in this order. The low acoustic velocity region may be provided by both increasing the electrode finger width, and providing the mass addition film.

The mass addition film may be made of a suitable dielectric or a suitable metal. It is to be noted, however, that if the mass addition film is made of a metal, a single mass addition film is not in contact with a plurality of electrode fingers connected to different potentials.

A piston mode is established as the central region and the low acoustic velocity region are arranged in this order from the central side toward the outer side in the direction in which the pair of busbars are located across the electrode region from each other. This makes it possible to reduce or prevent transverse modes, which are spurious waves. Preferably, the low acoustic velocity region is provided in both of the pair of edge regions. This makes it possible to reduce or prevent transverse modes more reliably.

FIG. 42 is a schematic plan view of an acoustic wave device according to a twelfth example embodiment of the present invention.

The twelfth example embodiment differs from the first example embodiment in that the absolute value of the inclination angle of a first envelope E91 relative to the propagation axis of the piezoelectric layer 6 is not constant. The twelfth example embodiment differs from the first example embodiment also in that the number of electrode finger pairs between mutually adjacent bends V1 of the first envelope E91 is not constant. Further, the twelfth example embodiment differs from the first example embodiment also in that the second envelope E102 has a straight shape, and how a second busbar 95 is configured. The twelfth example embodiment differs from the first example embodiment also in that the intersecting region includes a single curved region, and a single straight region. In accordance with the above-described differences, the twelfth example embodiment differs from the first example embodiment also in the shape of each reflector. The acoustic wave device according to the twelfth example embodiment is otherwise the same or similar in configuration to the acoustic wave device 1 according to the first example embodiment.

According to the twelfth example embodiment, the straight region in the intersecting region is one of the pair of edge regions. The pair of edge regions of the intersecting region specifically include a first edge region H1 and a second edge region H2. The first edge region H1 includes the first envelope E91. The second edge region H2 includes the second envelope E102. More specifically, the first edge region H1 is the region where the distal end portions of a plurality of second electrode fingers 97, and portions of a plurality of first electrode fingers 96 that are portions adjacent to the corresponding second electrode fingers 97 are located. The second edge region H2 is the region where the distal end portions of the first electrode fingers 96, and portions of the second electrode fingers 97 that are portions adjacent to the corresponding first electrode fingers 96 are located.

The straight region in the intersecting region is the second edge region H2. The curved region includes the first edge region H1, and a central region J.

The first envelope E91 has a shape defined by connecting mutually adjacent bends V1 by a straight line. The first envelope E91 thus includes a plurality of line segments defining a plurality of straight portions. The line segments of the first envelope E91 include a plurality of first line segments e1, and a plurality of second line segments e2. The first and second line segments e1 and e2 are connected alternately. The location where the first and second line segments e1 and e2 are connected with each other correspond to the bend V1.

Hereinafter, a positive direction of the angle at which an envelope is inclined relative to the propagation axis of the piezoelectric layer 6 is defined as the counterclockwise direction in plan view. According to the twelfth example embodiment, when the inclination angle of the first line segment e1 relative to the propagation axis is defined as a first inclination angle θ1, the first inclination angle θ1 has a positive sign. As with the first example embodiment, in the piezoelectric layer 6, the propagation axis is in the X-propagation direction.

When the inclination angle of the second line segment e2 relative to the propagation axis is defined as a second inclination angle θ2, the sign of the first inclination angle θ1, and the sign of the second inclination angle θ2 are different from each other. According to the twelfth example embodiment, the second inclination angle θ2 has a negative sign.

The number of electrode finger pairs on the first line segment e1 is less than the number of electrode finger pairs on the second line segment e2. In this regard, the number of electrode finger pairs on each of the first line segments e1 is the same. Similarly, the number of electrode finger pairs on each of the second line segments e2 is the same.

According to the twelfth example embodiment, for example, the first inclination angle θ1 is about 20°, and the second inclination angle θ2 is about −10°. Consequently, the absolute value of the first inclination angle θ1 is greater than the absolute value of the second inclination angle θ2. The first inclination angle θ1 and the second inclination angle θ2 need not necessarily have the values described above. When the condition |θ1|>|θ2| is met, transverse modes can be effectively reduced without an increase in the size of the acoustic wave device. This will now be explained in detail.

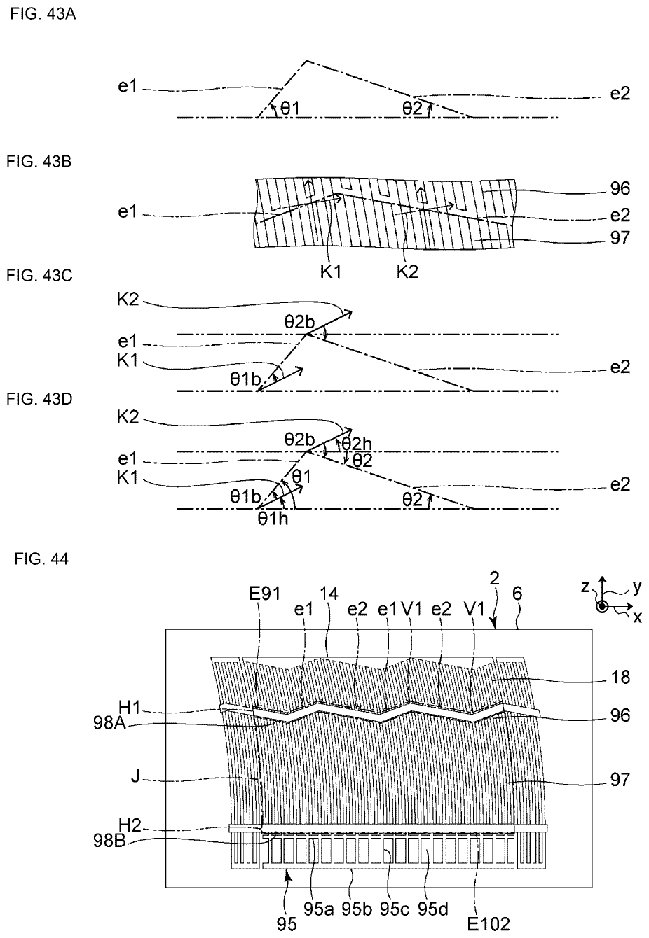

FIGS. 43A to 43D schematically illustrate angles defined for first and second line segments of the first envelope. The two-dot chain lines in FIGS. 43A to 43D are imaginary lines extending parallel or substantially parallel to the propagation axis of the piezoelectric layer. In FIGS. 43A to 43D, the sign of each angle is indicated by the direction of an arrow. If the direction of an arrow is counterclockwise, the sign of the angle represented by the arrow is positive.

As illustrated in FIG. 43A, the first inclination angle θ1 and the second inclination angle θ2 are defined with reference to the direction in which the propagation axis of the piezoelectric layer extends.

The reference for the angles associated with the first and second line segment e1 and e2 may also be defined based on the shape of each electrode finger. More specifically, for example, a normal K1 and a normal K2, each of which is the normal to the electrode finger in FIG. 43B, may define and function as the reference for the angles associated with the first and second line segments e1 and e2. As illustrated in FIG. 43C, the angle between the normal K1 to the electrode finger, and the first line segment e1 is defined as θ1b. The angle between the normal K2 to the electrode finger, and the second line segment e2 is defined as θ2b.

More specifically, the direction in which each electrode finger extends differs for each portion of the electrode finger. The angle θ1b is the angle at which the first line segment e1 is inclined relative to the normal K1 to the distal end portion of the second electrode finger 97 located on the first line segment e1. As illustrated in FIG. 43D, when the angle between the normal K1 and the propagation axis of the piezoelectric layer is defined as θ1h, θ1−θ1h=θ1b.

A positive direction of the angle between the propagation axis of the piezoelectric layer, and the normal to the electrode finger is defined as the counterclockwise direction in plan view. According to the twelfth example embodiment, the first inclination angle θ1 and the angle θ1h both have a positive sign. Consequently, the absolute value of the angle θ1b is equal to the difference between the absolute value of the first inclination angle θ1, and the absolute value of the angle θ1h. Therefore, when θ1>θ1h, the greater the absolute value of the first inclination angle θ1, the greater the absolute value of the angle θ1b.

The angle θ2b is the angle at which the second line segment e2 is inclined relative to the normal K2 to the distal end portion of the second electrode finger 97 located on the second line segment e2. When the angle between the normal K2 and the propagation axis of the piezoelectric layer is defined as θ2h, θ2−θ2h=θ2b. According to the twelfth example embodiment, the second inclination angle θ2 has a negative sign, and the angle θ2h has a positive sign. Consequently, the absolute value of the angle θ2b is equal to the sum of the absolute value of the second inclination angle θ2, and the absolute value of the angle θ2h. Therefore, the greater the absolute value of the second inclination angle θ2, the greater the absolute value of the angle θ2b. The direction of the normal to the electrode finger is

the first kind of direction among the directions previously exemplified as the direction of acoustic wave excitation. In some cases, the direction of acoustic wave excitation does not coincide with the above-described direction of the normal corresponding to the first kind of direction. However, the direction of acoustic wave excitation is at least nearly coincident with the direction of the normal. The angle θ1b is the angle between the normal K1 to the electrode finger, and the first line segment e1. Therefore, the greater the absolute value of the angle θ1b, the greater the inclination of the first line segment e1 relative to the direction of acoustic wave excitation. Similarly, the greater the absolute value of the angle θ2b, the greater the inclination of the second line segment e2 relative to the direction of acoustic wave excitation.

Returning now to FIG. 42, the greater the inclination of the first line segment e1 or the second line segment e2 of the first envelope E91 relative to the direction of acoustic wave excitation, the more effective the reduction of transverse modes. That is, the greater the absolute value of the angle θ1b or the absolute value of the angle θ2b, the more effective the reduction of transverse modes.

For example, a dimension of the first envelope E91 that corresponds to the amplitude of its wavy shape can be increased by increasing both the absolute value of the first inclination angle θ1 and the absolute value of the second inclination angle θ2. This, however, leads to an increased size of the acoustic wave device unless the intersecting region is reduced in area.

In an alternative example, a dimension of the first envelope E91 that corresponds to the period of its wavy shape can be decreased by increasing both the absolute value of the angle θ1b and the absolute value of the angle θ2b. This, however, leads to reduced number of electrode fingers between mutually adjacent bends V1. This may in turn decrease the transverse mode reduction effect.

In this regard, as described above, the absolute value of the angle θ2b is equal to the sum of the absolute value of the second inclination angle θ2, and the absolute value of the angle θ2h. This means that the absolute value of the angle θ2b is sufficiently large even when the second inclination angle θ2 is small. In contrast, the absolute value of the angle θ1b is equal to the difference between the absolute value of the first inclination angle θ1, and the absolute value of the angle θ1h. This means that the absolute value of the angle θ1b can be effectively increased by increasing the absolute value of the first inclination angle θ1.

According to the twelfth example embodiment, the absolute value of the first inclination angle θ1 is greater than the absolute value of the second inclination angle θ2. Consequently, the absolute value of the angle θ1b, and the absolute value of the angle θ2b can be increased without increasing the dimension of the first envelope E91 corresponding to the amplitude of the wavy shape, or decreasing the dimension of the first envelope E91 corresponding to the period of the wavy shape. This enables effective reduction of transverse modes without an increase in the size of the acoustic wave device.

The first envelope according to the first example embodiment or other example embodiments described above also includes first and second line segments. However, for example, according to the first example embodiment, the absolute value of the first inclination angle θ1, and the absolute value of the second inclination angle θ2 are the same or substantially the same.

According to the twelfth example embodiment, as with the first example embodiment, the first envelope E91 includes the first line segments e1 and the second line segments e2, which are inclined relative to the propagation axis, and include the bends V1. This makes it possible to reduce spurious waves, and improve the Q factor.

The first inclination angle θ1 need not necessarily have a positive sign. It may suffice that the first inclination angle θ1 and the angle θ1h have the same sign. For example, if the IDT electrode and the reflectors are reversed in shape relative to those according to the twelfth example embodiment with respect to the left-right direction in FIG. 42, then the first inclination angle θ1 and the angle θ1h have a negative sign.

According to the twelfth example embodiment, the first and second line segments e1 and e2 are connected alternately across the entire first envelope E91. It may suffice that the first envelope E91 includes at least one first line segment e1, and at least one second line segment e2. It may suffice that the first line segment e1 and the second line segment e2 are connected in at least a portion of the first envelope E91. It may suffice that the absolute value of the first inclination angle θ1 is greater than the absolute value of the second inclination angle θ2. In such cases as well, spurious waves outside the pass band can be reduced, and the Q factor can be improved. In addition, transverse modes can be effectively reduced.

The dimension of the first envelope E91 corresponding to the period of the wavy shape, and the dimension of the first envelope E91 corresponding to the amplitude of the wavy shape are constant. Alternatively, at least one of the dimension of the first envelope E91 corresponding to the period of the wavy shape, or the dimension of the first envelope E91 corresponding to the amplitude of the wavy shape may not be constant.

As illustrated in FIG. 42, the second busbar 95 is includes a plurality of openings 95d. More specifically, the second busbar 95 includes an inner busbar portion 95a, an outer busbar portion 95b, and a plurality of connection portions 95c. The inner busbar portion 95a and the outer busbar portion 95b are opposed to each other. Of the inner busbar portion 95a and the outer busbar portion 95b, the inner busbar portion 95a is located near the intersecting region. The connection portions 95c connect the inner busbar portion 95a and the outer busbar portion 95b. Each of the openings 95d is an opening bounded by the inner busbar portion 95a, the outer busbar portion 95b, and the connection portion 95c.

The inner busbar portion 95a extends parallel or substantially parallel to the second envelope E102. The inner busbar portion 95a faces each of the first electrode fingers 96 across a gap.

According to the twelfth example embodiment, each of the connection portions 95c of the second busbar 95 extends on an extended line of the second electrode finger 97. The connection portions 95c are not located on an extended line of the first electrode finger 96. In the intersecting region, the first and second electrode fingers 96 and 97 are arranged alternately. Consequently, the acoustic velocity in a region of the second busbar 95 where the openings 95d exist is higher than the acoustic velocity in the intersecting region. A high acoustic velocity region is thus provided in the region of the second busbar 95 where the openings 95d exist. The high acoustic velocity region refers to the region in which the acoustic velocity is higher than the acoustic velocity in the central region J.

As the primary mode undergoes mode conversion, leakage of acoustic wave energy may occur. For example, when shear horizontal (SH) waves are used as the primary acoustic wave mode, the acoustic wave energy may leak due to conversion from SH waves to Rayleigh waves or from SH waves to bulk waves. Such leakage occurs from the intersecting region toward the busbars.

According to the twelfth example embodiment, the inner busbar portion 95a of the second busbar 95 faces each of the first electrode fingers 96 across a gap. This makes it possible to reduce the leakage of acoustic wave energy associated with mode conversion.

The distance between the inner busbar portion 95a and the first electrode finger 96 is, for example, preferably less than or equal to about 0.5λ. This makes it possible to effectively reduce the leakage of acoustic wave energy associated with mode conversion.

For the case where the first envelope E91 is configured as in the twelfth example embodiment as well, the acoustic wave device may be configured to be capable of using the piston mode. This example will now be described with reference to first and second modifications of the twelfth example embodiment. As with the twelfth example embodiment, the first and second modifications make it possible to reduce spurious waves outside the pass band, and improve the Q factor. In addition, the first and second modifications make it possible to further reduce transverse modes without increasing the size of the acoustic wave device.

According to the first modification in FIG. 44, a low acoustic velocity region is provided in each of the first edge region H1 and the second edge region H2. More specifically, a single mass addition film 98A is disposed in the first edge region H1. In the first edge region H1, the single mass addition film 98A is disposed over a plurality of electrode fingers. The mass addition film 98A is disposed also in a portion of the piezoelectric layer 6 between the electrode fingers.

The first envelope E91 has a wavy shape. Thus, the respective distal end portions of the second electrode fingers 97 are also arranged in a wavy configuration. The first edge region H1 is the region where the distal end portion of each second electrode finger 97, and a portion of each first electrode finger 96 that is a portion adjacent to the distal end portion of the corresponding second electrode finger 97 are located. The first edge region H1 thus has a wavy shape. Accordingly, the mass addition film 98A also has a wavy shape.

A single mass addition film 98B is disposed in the second edge region H2. The mass addition film 98B is band-shaped. More specifically, in the second edge region H2, the single mass addition film 98B is disposed over a plurality of electrode fingers. The mass addition film 98B is disposed also in a portion of the piezoelectric layer 6 between the electrode fingers.

Due to the presence of the mass addition film 98A and the mass addition film 98B, a low acoustic velocity region is provided in each of the first edge region H1 and the second edge region H2.

As previously described, according to example embodiments of the present invention, there is no particular limitation on the order in which the mass addition film and the electrode finger are stacked.

It may suffice that the mass addition film is stacked with at least one electrode finger. However, the mass addition film is stacked preferably with a plurality of electrode fingers, and more preferably, with all of the electrode fingers. This allows the piston mode to be established more reliably.

A plurality of mass addition films may be disposed in the each edge region. In this case, it may suffice that each mass addition film is stacked with at least one electrode finger.

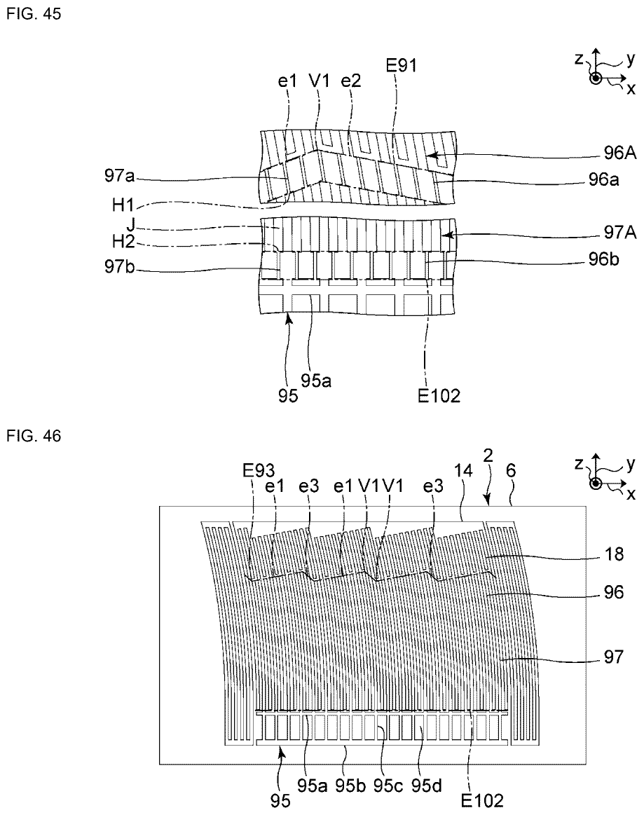

According to the second modification in FIG. 45, the electrode fingers include a widened portion. Each of the electrode fingers has a width in the widened portion greater than the width of the electrode finger in the central region J. More specifically, in the first edge region H1, a plurality of first electrode fingers 96A include a widened portion 96a. In the second edge region H2, the first electrode fingers 96A include a widened portion 96b. Similarly, in the first edge region H1, a plurality of second electrode fingers 97A include a widened portion 97a. In the second edge region H2, the second electrode fingers 97A include a widened portion 97b. Due to the configuration mentioned above, a low acoustic velocity region is provided in each of the first edge region H1 and the second edge region H2.

It may suffice that in the first edge region H1, at least one electrode finger includes a widened portion. However, in the first edge region H1, preferably a plurality of electrode fingers include a widened portion, and more preferably, all of the electrode fingers include a widened portion. The same as above also applies to the second edge region H2. This allows the piston mode to be established more reliably.

According to example embodiments of the present invention such as the twelfth example embodiment or the first example embodiment, a plurality of electrode finger pairs are located between mutually adjacent bends of the first envelope. One or more electrode finger pairs need not necessarily be located between mutually adjacent bends of the first envelope. This example will now be described with reference to a thirteenth example embodiment of the present invention.

FIG. 46 is a schematic plan view of an acoustic wave device according to the thirteenth example embodiment.

The thirteenth example embodiment differs from the twelfth example embodiment in that a first envelope E93 includes the first line segments e1 and a plurality of third line segments e3, and includes no second line segment e2. The acoustic wave device according to the thirteenth example embodiment is otherwise the same or similar in configuration to the acoustic wave device according to the twelfth example embodiment.

The first and third line segments e1 and e3 of the first envelope E93 are connected alternately. The location where the first and third line segments e1 and e3 are connected with each other corresponds to the bend V1.

Among the electrode fingers, only one first electrode finger 96 is located on the third line segment e3. That is, for example, about 0.5 pairs of electrode fingers are located on the third line segment e3. The distal end portion of the second electrode finger 97 is not located on the third line segment e3. At each of the bends V1 connected with the opposite ends of the third line segment e3, the distal end portion of the second electrode finger 97 is located. The third line segment e3 connects the respective distal end portions of two mutually adjacent second electrode fingers 97 each located at the corresponding one of mutually adjacent bends V1.

According to the thirteenth example embodiment, mutually adjacent first line segments e1 overlap each other when viewed in the direction in which the propagation axis of the piezoelectric layer 6 extends. Consequently, the dimension of the intersecting region in the direction normal to the propagation axis changes abruptly at the location of the third line segment e3 of the first envelope E93.

Transverse modes are standing waves that occur in the direction from the intersecting region toward the busbars. Due to the abrupt change in the dimension of the intersecting region in the direction normal to the propagation axis, the transverse modes become unstable. As a result, the transverse modes can be effectively reduced.

In addition, according to the thirteenth example embodiment, a portion of each electrode finger located in the intersecting region, and each reflector are the same or similar in configuration to those according to the twelfth example embodiment. The first envelope E93 includes the first line segments e1 that are inclined relative to the propagation axis, and the bends V1. This makes it possible to reduce spurious waves and transverse modes that are outside the pass band, and improve the Q factor.

It may suffice that mutually adjacent first line segments e1 overlap each other at least in a portion when viewed in the direction in which the propagation axis of the piezoelectric layer 6 extends. In this case as well, the dimension of the intersecting region in the direction normal to the propagation axis changes abruptly at the location of the third line segment e3 of the first envelope E93. This makes it possible to reduce transverse modes.

According to the thirteenth example embodiment, the first and third line segments e1 and e3 are connected alternately across the entire or substantially the entire first envelope E93. It may suffice, however, that in at least a portion of the first envelope E93, two first line segments e1 are connected by the third line segment e3.

The first line segments e1 have the same or substantially the same first inclination angle θ1, and the same or substantially the same length. Alternatively, the first line segments e1 connected by the same third line segment e3 need not necessarily have the same or substantially the same first inclination angle θ1, and need not necessarily have the same length. For example, at least one of the dimension of the first envelope E93 corresponding to the period of the wavy shape, or the dimension of the first envelope E93 corresponding to the amplitude of the wavy shape may not be constant.

It may suffice that the first envelope E93 includes at least two line segments inclined relative to the propagation axis of the piezoelectric layer 6, and at least one third line segment e3. It may suffice that the third line segment e3 is connected at opposite ends to the two line segments. It may suffice that the respective inclination angles of the two line segments connected to the same third line segment e3 have the same sign. According to the thirteenth example embodiment, the two line segments connected to the same third line segment e3 are the first line segments e1, and the first inclination angle θ1 has a positive sign.

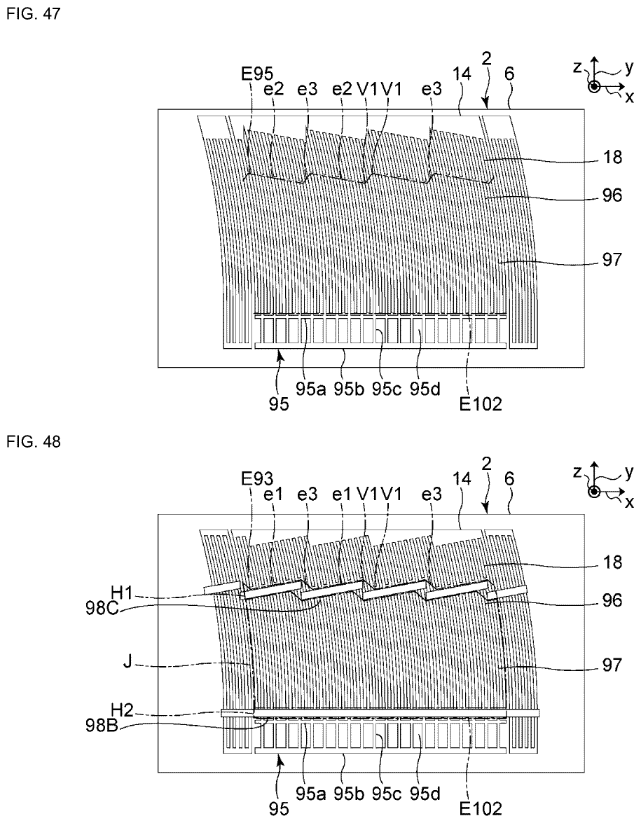

The respective inclination angles of the two line segments connected to the same third line segment e3 may have a negative sign. For example, according to the first modification of the thirteenth example embodiment in FIG. 47, a first envelope E95 includes the second line segments e2 and the third line segments e3, and includes no first line segment e1.

The second and third line segments e2 and e3 of the first envelope E95 are connected alternately. The distal end portion of the second electrode finger 97 is not located on the third line segment e3. At each of the bends V1 connected with the opposite ends of the third line segment e3, the distal end portion of the second electrode finger 97 is located.

According to the first modification, mutually adjacent second line segments e2 overlap each other when viewed in the direction in which the propagation axis of the piezoelectric layer 6 extends. Consequently, the dimension of the intersecting region in the direction normal to the propagation axis changes abruptly at the location of the third line segment e3 of the first envelope E95. As a result, transverse modes can be effectively reduced. In addition, according to the first modification, as with the thirteenth example embodiment, spurious waves outside the pass band can be reduced, and the Q factor can be improved.

It may suffice that mutually adjacent second line segments e2 overlap each other at least in a portion when viewed in the direction in which the propagation axis of the piezoelectric layer 6 extends. In this case as well, the dimension of the intersecting region in the direction normal to the propagation axis changes abruptly at the location of the third line segment e3 of the first envelope E95. This makes it possible to reduce transverse modes.

According to the first modification, the second and third line segments e2 and e3 are connected alternately across the entire or substantially the entire first envelope E95. It may suffice, however, that in at least a portion of the first envelope E95, two second line segments e2 are connected by the third line segment e3.

The second line segments e2 have the same or substantially the same second inclination angle θ2, and the same or substantially the same length. The second line segments e2 connected by the same third line segment e3 need not necessarily have the same or substantially the same second inclination angle θ2, and need not necessarily have the same or substantially the same length. For example, at least one of the dimension of the first envelope E95 corresponding to the period of the wavy shape, or the dimension of the first envelope E95 corresponding to the amplitude of the wavy shape may not be constant.

For the case where the first envelope is configured as in the thirteenth example embodiment or the first modification thereof as well, the acoustic wave device may be configured to be capable of using the piston mode. This example will now be described with reference to second and third modifications of the thirteenth example embodiment. As with the thirteenth example embodiment, the second and third modifications make it possible to reduce spurious waves outside the pass band, and improve the Q factor. In addition, the second and third modifications make it possible to further reduce transverse modes without increasing the size of the acoustic wave device.

According to the second modification in FIG. 48, the first envelope E93 includes the first line segments e1, and the third line segments e3. A plurality of mass addition films 98C are disposed in the first edge region H1. A single mass addition film 98B is disposed in the second edge region H2.

In the first edge region H1, the mass addition films 98C are disposed periodically. More specifically, each of the mass addition films 98C is disposed along the corresponding one of the first line segments e1 of the first envelope E93. Each mass addition film 98C is disposed over a plurality of electrode fingers. Each mass addition film 98C is disposed also in a portion of the piezoelectric layer 6 between the electrode fingers. No mass addition film 98C is disposed along the third line segment e3.

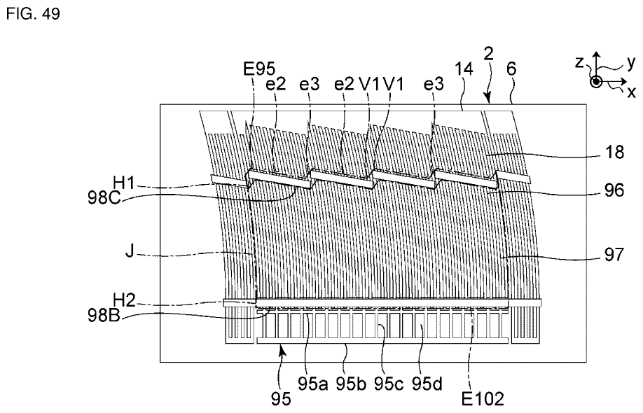

According to the third modification in FIG. 49, the first envelope E95 includes the second line segments e2, and the third line segments e3. The mass addition films 98C are disposed in the first edge region H1. A single mass addition film 98B is disposed in the second edge region H2.

In the first edge region H1, the mass addition films 98C are disposed periodically. More specifically, each of the mass addition films 98C is disposed along the corresponding one of the second line segments e2 of the first envelope E95. Each mass addition film 98C is disposed over a plurality of electrode fingers. Each mass addition film 98C is disposed also in a portion of the piezoelectric layer 6 between the electrode fingers. No mass addition film 98C is disposed along the third line segment e3.

According to the second modification and the third modification, the mass addition films 98C are disposed across the entire or substantially the entire first edge region H1 when viewed in the direction normal to the propagation axis of the piezoelectric layer 6. This makes it possible to effectively reduce transverse modes.

The second modification and the third modification may have, instead of the configuration in which the mass addition films are provided, a configuration in which at least one electrode finger includes a widened portion in at least one of the pair of edge regions. Alternatively, the low acoustic velocity region may be provided by both of the configuration in which the electrode finger includes a widened portion and the configuration in which the mass addition films are provided.

In the foregoing description of each of the twelfth and thirteenth example embodiments and the modifications thereof, an example of the second busbar and an example of the second envelope have been described. Alternatively, however, the twelfth and thirteenth example embodiments and the modifications thereof may include the second busbar and the second envelope according to other example embodiments of the present invention. The twelfth and thirteenth example embodiments and the modifications thereof may have a configuration in which the second offset electrodes are provided.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer;
an IDT electrode on the piezoelectric layer, and including a pair of busbars and a plurality of electrode fingers; and
a pair of reflectors on the piezoelectric layer, being opposed to each other across the IDT electrode and each including a plurality of reflector electrode fingers; wherein
the pair of busbars include a first busbar and a second busbar opposed to each other;
the plurality of electrode fingers include a plurality of first electrode fingers and a plurality of second electrode fingers;
the plurality of first electrode fingers are each connected at one end to the first busbar;
the plurality of second electrode fingers are each connected at one end to the second busbar;
the plurality of first electrode fingers are interdigitated with the plurality of second electrode fingers;
an imaginary line connecting distal end portions of the plurality of second electrode fingers is defined as a first envelope;
an imaginary line connecting distal end portions of the plurality of first electrode fingers is defined as a second envelope;
the IDT electrode includes an intersecting region between the first envelope and the second envelope;
the piezoelectric layer includes a propagation axis;
the plurality of first electrode fingers and the plurality of second electrode fingers each have a shape in plan view that includes a curved portion in the intersecting region;
the plurality of reflector electrode fingers each have a shape in plan view that includes a curved portion; and
at least one of the first envelope or the second envelope includes a portion extending at an inclination relative to the propagation axis, and includes at least one bend at which a direction in which the portion extends changes.

2. The acoustic wave device according to claim 1, wherein at least about 50% of the plurality of electrode fingers include a portion at which a direction normal to a direction in which the at least about 50% of the plurality of electrode fingers extend is aligned with a direction in which the propagation axis extends.

3. The acoustic wave device according to claim 1, wherein the plurality of first electrode fingers and the plurality of second electrode fingers each have a shape in plan view that includes a shape of a circular arc or an elliptical arc.

4. The acoustic wave device according to claim 3, wherein
a center of a circle including the circular arc defining the shape of each of the plurality of first electrode fingers and the plurality of second electrode fingers, or a centroid of two foci of an ellipse including the elliptical arc defining the shape of each of the plurality of first electrode fingers and the plurality of second electrode fingers is defined as a fixed point;
a portion of the intersecting region is defined as an excitation portion, and is located on a straight line passing through the fixed point;
a straight line extending parallel or substantially parallel to the propagation axis and passing through the fixed point is defined as a reference line; and
when an angle and an excitation angle are defined, the angle being between the reference line and a straight line passing through the fixed point and through the excitation portion, the excitation angle being between the reference line and a direction, the direction being a direction of acoustic wave excitation at a point of intersection between each of the plurality of electrode fingers and the straight line passing through the fixed point and through the excitation portion, for a plurality of the excitation portions, at least one of a duty ratio, an electrode finger pitch, or a thickness of each of the plurality of first electrode fingers and the plurality of second electrode fingers is varied in accordance with the angle or the excitation angle in each of the excitation portions to make all of the excitation portions have same or substantially same resonant frequencies or anti-resonant frequencies.

5. The acoustic wave device according to claim 3, further comprising:
a dielectric film on the piezoelectric layer to cover the IDT electrode; wherein
a center of a circle including the circular arc defining the shape of each of the plurality of first electrode fingers and the plurality of second electrode fingers, or a centroid of two foci of an ellipse including the elliptical arc defining the shape of each of the plurality of first electrode fingers and the plurality of second electrode fingers is defined as a fixed point;
a portion of the intersecting region is defined as an excitation portion, and being located on a straight line passing through the fixed point;
a straight line extending parallel or substantially parallel to the propagation axis and passing through the fixed point is defined as a reference line; and
when an angle and an excitation angle are defined, the angle being between the reference line and a straight line passing through the fixed point and through the excitation portion, the excitation angle being between the reference line and a direction, the direction being a direction of acoustic wave excitation at a point of intersection between each of the plurality of electrode fingers and the straight line passing through the fixed point and through the excitation portion, for a plurality of the excitation portions, a thickness of the dielectric film is varied in accordance with the angle or the excitation angle in each of the excitation portions to make all of the excitation portions have same or substantially same resonant frequencies or anti-resonant frequencies.

6. The acoustic wave device according to claim 1, wherein
each of the plurality of first electrode fingers has a shape in plan view that includes, in the intersecting region, at least two curved portions differing in a direction in which the plurality of first electrode fingers are curved, and at least one inflection point; and
each of the plurality of second electrode fingers has a shape in plan view that includes, in the intersecting region, at least two curved portions differing in a direction in which the plurality of second electrode fingers is curved, and at least one inflection point.

7. The acoustic wave device according to claim 6, wherein
the at least two curved portions defining the shape of each of the plurality of first electrode fingers and the plurality of second electrode fingers in plan view each include a shape of a circular arc or an elliptical arc; and
the intersecting region includes at least two curved regions where the plurality of first electrode fingers and the plurality of second electrode fingers each have a shape of a single circular arc or a single elliptical arc in plan view.

8. The acoustic wave device according to claim 7, wherein
for each of the curved regions, a center of a circle including the circular arc defining the shape of each of the plurality of first electrode fingers and the plurality of second electrode fingers, or a centroid of two foci of an ellipse including the elliptical arc defining the shape of each of the plurality of first electrode fingers and the plurality of second electrode fingers is defined as a fixed point;
a portion of each of the curved regions is defined as an excitation portion, the portion being located on a straight line passing through the fixed point;
a straight line extending parallel or substantially parallel to the propagation axis and passing through the fixed point is defined as a reference line;
the curved regions include a curved region including the first envelope; and
when an angle and an excitation angle are defined, the angle being between the reference line and a straight line in the curved region including the first envelope, the straight line passing through the fixed point and through the excitation portion, the excitation angle being between the reference line and a direction in the curved region including the first envelope, the direction being a direction of acoustic wave excitation at a point of intersection between each of the electrode fingers and the straight line passing through the fixed point and through the excitation portion, for a plurality of the excitation portions in the curved region, at least one of a duty ratio, an electrode finger pitch, or a thickness of each of the plurality of first electrode fingers and the plurality of second electrode fingers is varied in accordance with the angle or the excitation angle in each of the excitation portions to make all of the excitation portions have same or substantially same resonant frequencies or anti-resonant frequencies.

9. The acoustic wave device according to claim 7, further comprising:
a dielectric film on the piezoelectric layer to cover the IDT electrode; wherein
in each of the curved regions, a center of a circle including the circular arc defining the shape of each of the plurality of first electrode fingers and the plurality of second electrode fingers, or a centroid of two foci of an ellipse including the elliptical arc defining the shape of each of the plurality of first electrode fingers and the plurality of second electrode fingers is defined as a fixed point;
a portion of each of the curved regions is defined as an excitation portion, the portion being located on a straight line passing through the fixed point;
a straight line extending parallel or substantially parallel to the propagation axis and passing through the fixed point is defined as a reference line;
the curved regions include a curved region including the first envelope; and
when an angle and an excitation angle are defined, the angle being between the reference line and a straight line in the curved region including the first envelope, the straight line passing through the fixed point and through the excitation portion, the excitation angle being between the reference line and a direction in the curved region including the first envelope, the direction being a direction of acoustic wave excitation at a point of intersection between each of the plurality of electrode fingers and the straight line passing through the fixed point and through the excitation portion, for a plurality of the excitation portions in the curved region, a thickness of the dielectric film is varied in accordance with the angle or the excitation angle in each of the excitation portions to make all of the excitation portions have same or substantially same resonant frequencies or anti-resonant frequencies.

10. The acoustic wave device according to claim 1, wherein in the intersecting region, the plurality of first electrode fingers and the plurality of second electrode fingers have a shape in plan view that includes a straight shape.

11. The acoustic wave device according to claim 1, wherein
the piezoelectric substrate includes a support substrate; and
the piezoelectric layer is on the support substrate.

12. The acoustic wave device according to claim 11, wherein the piezoelectric substrate includes an intermediate layer between the support substrate and the piezoelectric layer.

13. The acoustic wave device according to claim 11, wherein the piezoelectric substrate includes a hollow, and a portion of the support substrate and a portion of the piezoelectric layer face each other across the hollow.

14. The acoustic wave device according to claim 1, wherein the piezoelectric substrate includes only the piezoelectric layer.

15. The acoustic wave device according to claim 1, further comprising:
a plurality of first offset electrodes, and a plurality of second offset electrodes; wherein
the plurality of first offset electrodes are each connected to the first busbar, and the plurality of second offset electrodes are each connected to the second busbar; and
a distal end portion of each of the plurality of second electrode fingers, and a distal end portion of a corresponding one of the plurality of first offset electrodes face each other with a gap therebetween, and a distal end portion of each of the plurality of first electrode fingers, and a distal end portion of a corresponding one of the plurality of second offset electrodes face each other with a gap therebetween.

16. The acoustic wave device according to claim 15, wherein the plurality of first offset electrodes have a curved shape in plan view.

17. The acoustic wave device according to claim 15, wherein the plurality of first offset electrodes have a straight shape in plan view.

18. The acoustic wave device according to claim 1, wherein
the intersecting region includes:
a first edge region including the first envelope;
a second edge region including the second envelope; and
a central region interposed between the first edge region and the second edge region; and
the acoustic wave device further includes a mass addition film in at least one of the first edge region or the second edge region, and being stacked with at least one of the electrode fingers.

19. The acoustic wave device according to claim 1, wherein
the intersecting region includes:
a first edge region including the first envelope;
a second edge region including the second envelope; and
a central region interposed between the first edge region and the second edge region; and
at least one of the plurality of electrode fingers is located in at least one of the first edge region or the second edge region, and includes a widened portion wider than the central region.

20. The acoustic wave device according to claim 1, wherein
of the first envelope and the second envelope, at least the first envelope includes a plurality of the bends; and
the first envelope has a wavy shape.

21. The acoustic wave device according to claim 20, wherein
the first envelope has a wavy shape;
20 or more pairs of the plurality of electrode fingers are between the mutually adjacent bends of the first envelope; and
the first envelope includes a plurality of portions inclined relative to the propagation axis, and each of the plurality of portions of the first envelope inclined relative to the propagation axis has an inclination angle with an absolute value greater than or equal to about 5.5° relative to the propagation axis.

22. The acoustic wave device according to claim 21, wherein each of the plurality of portions of the first envelope inclined relative to the propagation axis has an inclination angle with an absolute value greater than or equal to about 7° relative to the propagation axis.

23. The acoustic wave device according to claim 22, wherein each of the plurality of portions of the first envelope inclined relative to the propagation axis has an inclination angle with an absolute value greater than or equal to about 10° relative to the propagation axis.

24. The acoustic wave device according to claim 20, wherein
the first envelope has a wavy shape;
the first envelope includes a plurality of portions inclined relative to the propagation axis, and each of the plurality of portions of the first envelope inclined relative to the propagation axis has an inclination angle with an absolute value greater than or equal to about 10° relative to the propagation axis; and
7 or more pairs of the plurality of electrode fingers are between the mutually adjacent bends of the first envelope.

25. The acoustic wave device according to claim 24, wherein 10 or more pairs of the plurality of electrode fingers are between the mutually adjacent bends of the first envelope.

26. The acoustic wave device according to claim 20, wherein
the first envelope has a wavy shape;
the first envelope includes at least one first line segment, and at least one second line segment connected to the first line segment; and
when a positive direction of an angle at which the first envelope and a normal to each of the plurality of electrode fingers are inclined relative to the propagation axis is defined as a counterclockwise direction in plan view, and an inclination angle of the first line segment relative to the propagation axis is defined as a first inclination angle, an angle at which a normal to a distal end portion of each of the second electrode fingers located on the first line segment is inclined relative to the propagation axis, and the first inclination angle are identical in sign;
when an inclination angle of the second line segment relative to the propagation axis is defined as a second inclination angle, the first inclination angle and the second inclination angle are different in sign; and
the first inclination angle has an absolute value greater than an absolute value of the second inclination angle.

27. The acoustic wave device according to claim 20, wherein
the first envelope has a wavy shape;
the first envelope includes at least two line segments inclined relative to the propagation axis, and at least one third line segment connected at opposite ends to the two line segments;
when a positive direction of an angle at which the first envelope is inclined relative to the propagation axis is defined as a counterclockwise direction in plan view, respective inclination angles, relative to the propagation axis, of the two line segments connected to the same third line segment are identical in sign; and
a distal end portion of none of the second electrode fingers is located on the third line segment, and when viewed in a direction in which the propagation axis extends, the two line segments connected to the same third line segments overlap each other at least in a portion thereof.

28. The acoustic wave device according to claim 26, wherein
the intersecting region includes:
a first edge region including the first envelope;
a second edge region including the second envelope; and
a central region interposed between the first edge region and the second edge region; and
the acoustic wave device further includes a mass addition film in at least one of the first edge region or the second edge region, the mass addition film being stacked with at least one of the plurality of electrode fingers.

29. The acoustic wave device according to claim 26, wherein
the intersecting region includes:
a first edge region including the first envelope;
a second edge region including the second envelope; and
a central region interposed between the first edge region and the second edge region; and
at least one of the plurality of electrode fingers is in at least one of the first edge region or the second edge region, and includes a widened portion wider than the central region.

30. The acoustic wave device according to claim 20, wherein
the second envelope includes a plurality of the bends;
the second envelope has a wavy shape;
the plurality of bends of the first envelope include a bend at which the first envelope is bent to protrude toward the first busbar, the plurality of bends of the second envelope include a bend at which the second envelope is bent to protrude toward the first busbar, and the bend at which the first envelope is bent to protrude toward the first busbar and the bend at which the second envelope is bent to protrude toward the first busbar are arranged in a direction orthogonal or substantially orthogonal to the propagation axis; and
the plurality of bends of the first envelope include a bend at which the first envelope is bent to protrude toward the second busbar, the plurality of bends of the second envelope include a bend at which the second envelope is bent to protrude toward the second busbar, and the bend where the first envelope is bent to protrude toward the second busbar and the bend where the second envelope is bent to protrude toward the second busbar are arranged in the direction orthogonal or substantially orthogonal to the propagation axis.

31. The acoustic wave device according to claim 20, wherein
the second envelope includes a plurality of the bends;
the second envelope has a wavy shape;
the plurality of bends of the first envelope include a bend at which the first envelope is bent to protrude toward the first busbar, the plurality of bends of the second envelope include a bend at which the second envelope is bent to protrude toward the second busbar, and the bend at which the first envelope is bent to protrude toward the first busbar and the bend at which the second envelope is bent to protrude toward the second busbar are arranged in a direction orthogonal or substantially orthogonal to the propagation axis; and
the plurality of bends of the first envelope include a bend at which the first envelope is bent to protrude toward the second busbar, the plurality of bends of the second envelope include a bend where the second envelope is bent to protrude toward the first busbar, and the bend at which the first envelope is bent to protrude toward the second busbar and the bend at which the second envelope is bent to protrude toward the first busbar are arranged in the direction orthogonal or substantially orthogonal to the propagation axis.

32. The acoustic wave device according to claim 20, wherein at least one of a dimension of the first envelope corresponding to a period of the wavy shape, or a dimension of the first envelope corresponding to an amplitude of the wavy shape is not constant.

33. The acoustic wave device according to claim 20, wherein
the second envelope includes a plurality of the bends;
the second envelope has a wavy shape; and
the first envelope and the second envelope differ from each other in at least one of a dimension corresponding to a period of the wavy shape, or a dimension corresponding to an amplitude of the wavy shape.

34. The acoustic wave device according to claim 20, wherein
the first busbar has a wavy shape in plan view in a portion near the first envelope; and
a distance between the first busbar and the first envelope in a direction orthogonal or substantially orthogonal to the propagation axis is constant.

35. The acoustic wave device according to claim 34, further comprising:
a plurality of first offset electrodes, and a plurality of second offset electrodes; wherein
the plurality of first offset electrodes are each connected to the first busbar, and the plurality of second offset electrodes are each connected to the second busbar;
a distal end portion of each of the plurality of second electrode fingers, and a distal end portion of a corresponding one of the plurality of first offset electrodes face each other with a gap therebetween, and a distal end portion of each of the plurality of first electrode fingers, and a distal end portion of a corresponding one of the plurality of second offset electrodes face each other with a gap therebetween; and
the plurality of first offset electrodes have a constant length.

36. The acoustic wave device according to claim 34, wherein
the second envelope includes a plurality of the bends;
the second envelope has a wavy shape;
the second busbar has a wavy shape in plan view in a portion adjacent to the second envelope; and
a distance between the second busbar and the second envelope in the direction orthogonal to the propagation axis is constant.

37. The acoustic wave device according to claim 20, wherein, of the first envelope and the second envelope, only the first envelope has the wavy shape.

38. The acoustic wave device according to claim 37, wherein the second envelope has a straight shape.

39. The acoustic wave device according to claim 34, wherein the second busbar has a straight shape in a portion near the second envelope.

40. A filter device comprising:
a plurality of acoustic wave resonators; wherein
at least one of the acoustic wave resonators is the acoustic wave device according to claim 1.

41. A filter device comprising:
a plurality of acoustic wave resonators; wherein
at least two of the acoustic wave resonators are each the acoustic wave device according to claim 34;
the acoustic wave device includes two acoustic wave devices; and
the first busbars of the two acoustic wave devices are connected with each other.

42. A filter device comprising:
a plurality of acoustic wave resonators; wherein
at least two of the acoustic wave resonators are each the acoustic wave device according to claim 39;
the acoustic wave device includes two acoustic wave devices; and
the second busbars of the two acoustic wave devices are connected with each other.
